(19) United States
(12) Patent Application Publication
(10) Pub. No.: US 2025/0149290 A1
(43) Pub. Date: May 8, 2025

(54) MULTIPLE-BEAM IMAGE ACQUISITION APPARATUS AND MULTIPLE-BEAM IMAGE ACQUISITION METHOD

(71) Applicant: NuFlare Technology, Inc., Yokohama-shi (JP)

(72) Inventors: Koichi ISHII, Kawasaki-shi (JP); Munehiro OGASAWARA, Hiratsuka-shi (JP); Yosuke ITO, Kamakura-shi (JP); Atsushi ANDO, Edogawa-ku (JP)

(73) Assignee: NuFlare Technology, Inc., Yokohama-shi (JP)

(21) Appl. No.: 19/009,276

(22) Filed: Jan. 3, 2025

Related U.S. Application Data
(63) Continuation of application No. PCT/JP2023/024462, filed on Jun. 30, 2023.

(30) Foreign Application Priority Data
Jul. 5, 2022 (JP) 2022-108528
Jun. 27, 2023 (JP) 2023-104658

(51) Int. Cl. H01J 37/317; H01J 37/147; H01J 37/20; H01J 37/22; H01J 37/244

(52) U.S. Cl. CPC H01J 37/3177; H01J 37/1471; H01J 37/20; H01J 37/222; H01J 37/244; H01J 2237/1501; H01J 2237/2448

(57) ABSTRACT

A multiple-beam image acquisition apparatus includes a stage to mount thereon a target object, a mark member, arranged on the stage, to include a base body having at least a surface made from the first material, plural isolated patterns, formed on the base body, having the same positional relationship as plural irradiation positions, flush in height with the surface of the target object, of plural beams having been determined previously in multiple primary electron beams, and being made from a material different from the first material, and an alignment mark, an electron optical system to irradiate the mark member with the multiple primary electron beams in the state where alignment of the multiple primary electron beams has been performed using the alignment mark, and a multi-detector to detect multiple secondary electron beams emitted from the mark member because the mark member is irradiated with the multiple primary electron beams.

### CROSS-REFERENCE TO RELATED APPLICATION

This application is a continuation application based upon and claims the benefit of priority from prior Japanese Patent Application No. 2022-108528 (application number) filed on Jul. 5, 2022 in Japan, Japanese Patent Application No. 2023-104658 (application number) filed on Jun. 27, 2023 in Japan, and International Application PCT/JP2023/024462, the International Filing Date of which is Jun. 30, 2023. The contents described in JP2022-108528, JP2023-104658 and PCT/JP2023/024462 are incorporated herein by reference.

### BACKGROUND OF THE INVENTION

### Field of the Invention

Embodiments of the present invention relate to a multiple-beam image acquisition apparatus and a multiple-beam image acquisition method, and for example, relate to a method for acquiring an image by applying multiple primary electron beams to a substrate and detecting multiple secondary electron beams emitted from the substrate due to the irradiation with the multiple primary electron beams.

### Description of Related Art

With recent progress in high integration and large capacity of the Large Scale Integrated circuits (LSI), the line width (critical dimension) necessary for circuits of semiconductor elements is becoming increasingly narrower. Since LSI manufacturing needs an enormous production cost, it is essential to improve the yield. However, as typified by 1 gigabit DRAMs (Dynamic Random Access Memories), the size of patterns that make up LSIs has been reduced to the order of nanometers from submicrons. Also, in recent years, with miniaturization of dimensions of LSI patterns formed on a semiconductor wafer, dimensions to be detected as a pattern defect have become extremely small. Therefore, the pattern inspection apparatus which inspects defects of ultrafine patterns exposed (transferred) to the semiconductor wafer needs to be highly accurate. Furthermore, one of major factors that decrease the yield is due to pattern defects on the mask used for exposing (transferring) ultrafine patterns onto the semiconductor wafer by the photolithography technology. Therefore, by acquiring, with such as electron beams, a pattern image of an exposure mask used for LSI manufacturing, defects of the exposure mask are inspected using the acquired image.

For example, a pattern image is acquired by applying multiple electron beams to an inspection target substrate and detecting a secondary electron corresponding to each beam emitted from the inspection target substrate. As an inspection method, there is known a method of comparing a measured image acquired by imaging a pattern formed on a substrate with design data or with another measured image acquired by imaging an identical pattern on the same substrate.

In the apparatus which simultaneously acquires each beam image by using multiple beams, it is important to perform an alignment between multiple secondary electron beams and a plurality of detection elements of the secondary electron detector. Accordingly, first, identifying four corner beams of multiple secondary electron beams is needed. Each beam position of multiple secondary electron beams can be acquired/calculated from secondary electron images obtained by a plurality of detection elements. However, there exist various beam positional relationships in the obtained images. Therefore, identifying a corner beam is not easy.

For example, there is disclosed a method where an aperture plate is arranged between the last stage lens of the secondary optical system lens and the secondary electron detector in order to use it for position adjustment of secondary electron beams (refer to, e.g., Japanese Patent Application Laid-open (JP-A) No. 2014-026834).

### BRIEF SUMMARY OF THE INVENTION

According to one aspect of the present invention, a multiple-beam image acquisition apparatus includes
a stage configured to mount thereon a target object,
a mark member arranged on the stage and configured to include a base body having at least a surface made from a first material, a plurality of isolated patterns, formed on the base body, having a same positional relationship as that of a plurality of irradiation positions, flush in height with a surface of the target object, of a plurality of beams having been determined in advance in multiple primary electron beams, and being made from a material different from the first material, and an alignment mark,
an electron optical system configured to irradiate the mark member with the multiple primary electron beams in a state where alignment of the multiple primary electron beams has been performed using the alignment mark, and
a multi-detector configured to detect multiple secondary electron beams emitted from the mark member due to that the mark member is irradiated with the multiple primary electron beams.

According to another aspect of the present invention, a multiple-beam image acquisition method includes
performing an alignment of multiple primary electron beams, using an alignment mark,
applying the multiple primary electron beams, in a state where the multiple primary electron beams have been aligned using the alignment mark, to a mark member, arranged on a stage to mount a target object thereon, which includes a base body having at least a surface made from a first material, a plurality of isolated patterns formed having a same positional relationship as that of a plurality of irradiation positions, flush in height with a surface of the target object, of a plurality of beams determined in advance in multiple primary electron beams, on the base body, and being made from a material different from the first material, and the alignment mark, and
detecting multiple secondary electron beams emitted from the mark member due to that the mark member is irradiated with the multiple primary electron beams, and outputting detected image data.

According to yet another aspect of the present invention, a multiple-beam image acquisition apparatus includes
a stage configured to mount thereon a target object and to be movable,
a mark member arranged on the stage and configured to include a base body having at least a surface made from a first material, and one isolated pattern, formed on the base body, being made from a material different from the first material,
an electron optical system configured to irradiate the mark member with multiple primary electron beams in a state where the stage has been moved so that the one isolated pattern is located at an irradiation position, flush in height with a surface of the target object, of a beam determined in advance in the multiple primary electron beams, and
a multi-detector configured to detect multiple secondary electron beams emitted from the mark member due to that the mark member is irradiated with the multiple primary electron beams.

According to yet another aspect of the present invention, a multiple-beam image acquisition method includes
moving a stage, which is to mount thereon a target object, so that one isolated pattern, included in a mark member which is arranged on the stage and includes a base body having at least a surface made from a first material and the one isolated pattern formed on the base body and made from a material different from the first material, is located at an irradiation position, flush in height with a surface of the target object, of a beam determined in advance in multiple primary electron beams,
irradiating the mark member with the multiple primary electron beams, in a state where the one isolated pattern is at the irradiation position, flush in height with the surface of the target object, of the beam determined in advance, and
detecting multiple secondary electron beams emitted from the mark member due to that the mark member is irradiated with the multiple primary electron beams, and outputting detected image data.

According to yet another aspect of the present invention, a multiple-beam image acquisition apparatus includes
a stage configured to mount thereon a target object,
a mark member arranged on the stage and configured to include a base body having at least a surface made from a first material, a plurality of isolated patterns, formed on the base body, having a same positional relationship as that of a plurality of irradiation positions, flush in height with a surface of the target object, of a plurality of beams determined in advance in multiple primary electron beams, and being made from a material different from the first material, and an alignment mark,
an electron optical system configured to irradiate one of the target object and the mark member with the multiple primary electron beams, and
a multi-detector configured to detect multiple secondary electron beams emitted due to that the one of the target object and the mark member is irradiated with the multiple primary electron beams.

### BRIEF DESCRIPTION OF THE DRAWINGS

FIG. 1 is a diagram showing an example of a configuration of an inspection apparatus according to a first embodiment;

FIG. 2 is a conceptual diagram showing a configuration of a shaping aperture array substrate according to the first embodiment;

FIG. 3 is an illustration showing an example of a detection image according to a comparative example of the first embodiment;

FIG. 4 is an illustration showing another example of a detection image according to the comparative example of the first embodiment;

FIG. 5 is an illustration showing another example of a detection image according to the comparative example of the first embodiment;

FIG. 6 is an illustration showing an example of a mark member according to the first embodiment;

FIG. 7 is an illustration showing another example of the mark member according to the first embodiment;

FIG. 8 is a block diagram showing an example of an internal configuration of an alignment circuit according to the first embodiment;

FIG. 9 is a flowchart showing an example of main steps of an inspection method according to the first embodiment;

FIG. 10 is an illustration showing an example of a secondary electron beam array according to the first embodiment;

FIG. 11 is an illustration showing examples of images each obtained by each detection element according to the first embodiment;

FIG. 12 is an illustration showing corner part images in image examples each acquired by each detection element according to the first embodiment;

FIG. 13 is an illustration showing a result of calculating a relative positional relationship between the detection element D11 and each of the beams B11, B12, B21, and B22, based on the output image of the detection element D11 in FIG. 12;

FIG. 14 is an illustration showing a result of calculating a relative positional relationship between the detection element D12 and each of the beams B11, B12, B21, and B22, based on the output image of the detection element D12 in FIG. 12;

FIG. 15 is an illustration showing a result of calculating a relative positional relationship between the detection element D21 and each of the beams B11, B12, B21, and B22, based on the output image of the detection element D21 in FIG. 12;

FIG. 16 is an illustration showing a result of calculating a relative positional relationship between the detection element D22 and each of the beams B11, B12, B21, and B22, based on the output image of the detection element D22 in FIG. 12;

FIG. 17 is an illustration showing an example of relation after synthesis between the position of each detection element and that of each beam according to the first embodiment;

FIG. 18 is an illustration showing an example of an entire positional relationship according to the first embodiment;

FIG. 19 is an illustration showing an example of a mark member according to a modified example of the first embodiment;

FIG. 20 is an illustration describing a method for identifying a beam positional relationship according to a modified example of the first embodiment;

FIG. 21 is an illustration showing an example of a plurality of chip regions formed on a semiconductor substrate, according to the first embodiment;

FIG. 22 is an illustration describing inspection processing according to the first embodiment;

FIG. 23 is a diagram showing an example of an internal configuration of a comparison circuit according to the first embodiment;

FIG. 24 is an illustration showing an example of a mark member according to a second embodiment;

FIG. 25 is a flowchart showing an example of main steps of an inspection method according to the second embodiment;

FIG. 26 is an illustration showing an example of a positional relationship between multiple primary electron beams and a mark member according to the second embodiment;

FIG. 27 is an illustration showing an example of a mark member according to a third embodiment;

FIG. 28 is a flowchart showing an example of main steps of an inspection method according to the third embodiment;

FIG. 29 is an illustration showing an example of positional relationship between multiple primary electron beams and a mark member according to the third embodiment;

FIG. 30 is an illustration showing an example of a mark member according to a fourth embodiment;

FIG. 31 is a flowchart showing an example of main steps of an inspection method according to the fourth embodiment; and

FIG. 32 is an illustration showing an example of positional relationship between multiple primary electron beams and a mark member according to the fourth embodiment.

### DETAILED DESCRIPTION OF THE INVENTION

Embodiments of the present invention provide an apparatus and method that can identify a desired beam in multiple secondary electron beams.

Embodiments below describe, as an example of a multiple-beam image acquisition apparatus, an inspection apparatus using multiple electron beams. However, it is not limited thereto. Any apparatus can be used that applies multiple primary electron beams to a substrate and detects multiple secondary electron beams emitted from the substrate by a multi-detector.

### First Embodiment

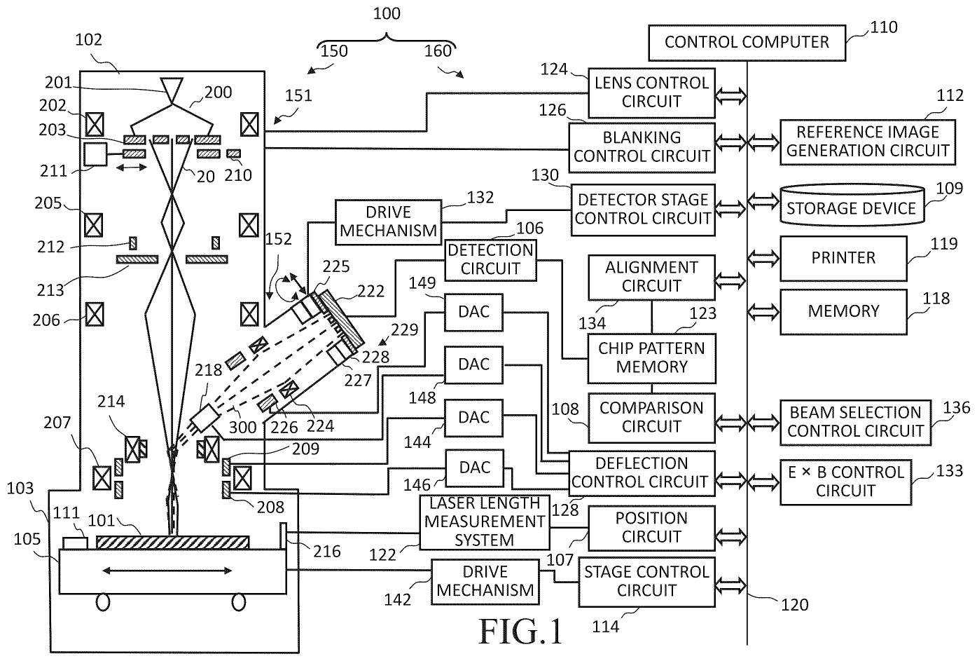

FIG. 1 is a diagram showing an example of a configuration of an inspection apparatus according to a first embodiment. In FIG. 1, an inspection apparatus 100 for inspecting a pattern formed on a substrate is an example of a multiple electron beam inspection apparatus. Furthermore, the inspection apparatus 100 is an example of a multiple-beam image acquisition apparatus. The inspection apparatus 100 includes an image acquisition mechanism 150 and a control system circuit 160. The image acquisition mechanism 150 includes an electron beam column 102 (electron optical column) and an inspection chamber 103. In the electron beam column 102, there are disposed an electron gun 201, an electromagnetic lens 202, a shaping aperture array substrate 203, a beam selection aperture substrate 210, a drive circuit 211, an electromagnetic lens 205, a collective blanking deflector 212, a limiting aperture substrate 213, an electromagnetic lens 206, an electromagnetic lens 207 (objective lens), a deflector 208, a deflector 209, an E×B separator 214 (beam separator), a deflector 218, a deflector 226, an electromagnetic lens 224, a detector stage 229, a detector aperture array substrate 225, and a multi-detector 222. A primary electron optical system 151 (illumination optical system) is composed of the electron gun 201, the electromagnetic lens 202, the shaping aperture array substrate 203, the beam selection aperture substrate 210, the electromagnetic lens 205, the collective blanking deflector 212, the limiting aperture substrate 213, the electromagnetic lens 206, the electromagnetic lens 207 (objective lens), the deflector 208, and the deflector 209. A secondary electron optical system 152 (detection optical system) is composed of the electromagnetic lens 207, the E×B separator 214, the deflector 218, the deflector 226, and the electromagnetic lens 224. The multi-detector 222 is arranged on the detector stage 229 which is movable in the x and y directions in the secondary coordinate system, and a rotation (θ) direction. The detector stage 229 includes a rotary stage 227, and an X-Y stage 228 of the secondary coordinate system for secondary electron beams.

In the inspection chamber 103, there is disposed a stage 105 movable at least in the x and y directions. On the stage 105, a substrate 101 (target object) to be inspected is placed. The substrate 101 may be an exposure mask substrate, or a semiconductor substrate such as a silicon wafer. In the case of the substrate 101 being a semiconductor substrate, a plurality of chip patterns (wafer die) are formed on the semiconductor substrate. In the case of the substrate 101 being an exposure mask substrate, a chip pattern is formed on the exposure mask substrate. The chip pattern is composed of a plurality of figure patterns. When the chip pattern formed on the exposure mask substrate is exposed and transferred onto the semiconductor substrate a plurality of times, a plurality of chip patterns (wafer die) are formed on the semiconductor substrate. The case of the substrate 101 being a semiconductor substrate is mainly described below. The substrate 101 is placed, with its pattern-forming surface facing upward, on the stage 105, for example. Furthermore, on the stage 105, there is disposed a mirror 216 which reflects a laser beam for measuring a laser length emitted from a laser length measuring system 122 arranged outside the inspection chamber 103. Moreover, on the XY stage 105, a mark member 111 adjusted to be flush in height with the surface of the substrate 101 is arranged.

The multi-detector 222 is connected, at the outside of the electron beam column 102, to a detection circuit 106. The detection circuit 106 is connected to a chip pattern memory 123.

The multi-detector 222 includes a plurality of detection elements arranged in an array (grid). In the detector aperture array substrate 225, a plurality of openings are formed at the array pitch of the plurality of detection elements. Each of the plurality of openings is a circle, for example. The center position of each opening is formed to be aligned with the center position of a corresponding detection element. The size of the opening is smaller than the region size of the electron detection surface of the detection element.

In the control system circuit 160, a control computer 110 which controls the whole of the inspection apparatus 100 is connected, through a bus 120, to a position circuit 107, a comparison circuit 108, a reference image generation circuit 112, a stage control circuit 114, a lens control circuit 124, a blanking control circuit 126, a deflection control circuit 128, a detector stage control circuit 130, an E×B control circuit 133, an alignment circuit 134, a beam selection control circuit 136, a storage device 109 such as a magnetic disk drive, a memory 118, and a printer 119. The deflection control circuit 128 is connected to DAC (digital-to-analog conversion) amplifiers 144, 146, 148 and 149. The DAC amplifier 146 is connected to the deflector 208, the DAC amplifier 144 is connected to the deflector 209, the DAC amplifier 148 is connected to the deflector 218, and the DAC amplifier 149 is connected to the deflector 226.

The chip pattern memory 123 is connected to the comparison circuit 108 and the alignment circuit 134. The stage 105 is driven by a drive mechanism 142 under the control of the stage control circuit 114. In the drive mechanism 142, for example, a drive system such as a three (x-, y-, and θ-) axis motor driving in the directions of x, y, and θ in the stage coordinate system is configured, and therefore, the stage 105 can be moved in the x, y, and θ directions. A step motor, for example, can be used as each of these x, y, and θ motors (not shown). The stage 105 is movable in the horizontal direction and the rotation direction by the x-, y-, and θ-axis motors. The movement position of the stage 105 is measured by the laser length measuring system 122, and supplied (transmitted) to the position circuit 107. Based on the principle of laser interferometry, the laser length measuring system 122 measures the position of the stage 105 by receiving a reflected light from the mirror 216. In the stage coordinate system, the x, y, and θ directions of the primary coordinate system are set, for example, with respect to the plane perpendicular to the optical axis of multiple primary electron beams 20.

The detector stage 229 is driven by a drive mechanism 132 under the control of the detector stage control circuit 130. In the drive mechanism 132, for example, a drive system such as a three (x-, y-, and θ-) axis motor driving in the directions of x, y, and θ in the stage coordinate system is configured, and therefore, the X-Y stage 228 can be moved in the x and y directions, and the rotary stage 227 can be moved in the θ direction. FIG. 1 shows the case where the X-Y stage 228 is arranged on the rotary stage 227. A step motor, for example, can be used as each of these x, y, and θ motors (not shown). The detector stage 229 is movable in the horizontal direction and the rotation direction by the x-, y-, and θ-axis motors. In the stage coordinate system, the x, y, and θ directions of the secondary coordinate system are set, for example, with respect to the plane perpendicular to the optical axis of multiple secondary electron beams 300. Alternatively, instead of the movement of the detector stage 229, the multiple secondary electron beams 300 may be optically moved by, for example, arranging an alignment coil such that a relative position between the multiple secondary electron beams 300 and the multi-detector 222 can be adjusted.

The electromagnetic lenses 202, 205, 206, 207, and 224 are controlled by the lens control circuit 124. The E×B separator 214 is controlled by the E×B control circuit 133. The drive circuit 211 is controlled by the beam selection control circuit 136. The collective blanking deflector 212 is an electrostatic deflector composed of two or more electrodes (or poles), and each electrode is controlled by the blanking control circuit 126 through a DAC amplifier (not shown). The deflector 209 is an electrostatic deflector composed of four or more electrodes (or poles), and each electrode is controlled by the deflection control circuit 128 through the DAC amplifier 144. The deflector 208 is an electrostatic deflector composed of four or more electrodes (or poles), and each electrode is controlled by the deflection control circuit 128 through the DAC amplifier 146. The deflector 218 is an electrostatic deflector composed of four or more electrodes (or poles), and each electrode is controlled by the deflection control circuit 128 through the DAC amplifier 148. The deflector 226 is an electrostatic deflector composed of four or more electrodes (or poles), and each electrode is controlled by the deflection control circuit 128 through the DAC amplifier 149.

In the beam selection aperture substrate 210, two sized apertures are formed: a large aperture through which all the multiple primary electron beams 20 can pass and a small aperture through which only a single primary electron beam can pass. By being horizontally moved in the x direction (or y direction) by the drive mechanism 211, the beam selection aperture substrate 210 switches the aperture on the beam trajectory between the large aperture and the small aperture.

To the electron gun 201, there is connected a high voltage power supply circuit (not shown). The high voltage power supply circuit applies an acceleration voltage between a filament (cathode) (not shown) and an extraction electrode (anode) (not shown) in the electron gun 201. In addition to the applying the acceleration voltage, a voltage is applied to another extraction electrode (Wehnelt), and the cathode is heated to a predetermined temperature, and thereby, electrons from the cathode are accelerated to be emitted as an electron beam 200.

FIG. 1 shows configuration elements necessary for describing the first embodiment. Other configuration elements generally necessary for the inspection apparatus 100 may also be included therein.

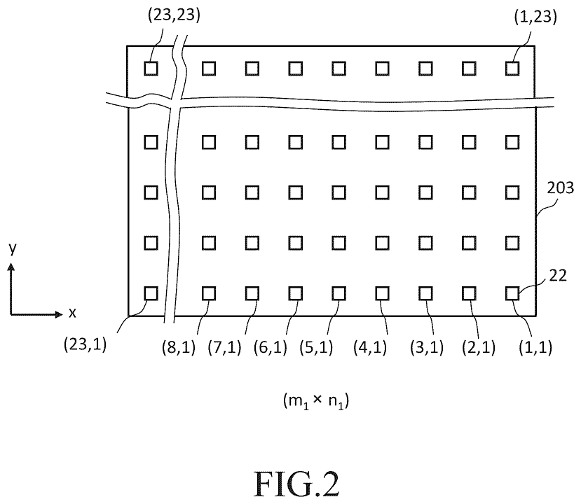

FIG. 2 is a conceptual diagram showing a configuration of a shaping aperture array substrate according to the first embodiment. As shown in FIG. 2, holes (openings) 22 of m₁ columns wide (in the x direction) and n₁ rows long (in the y direction), where each of m₁ and n₁ is an integer of 2 or more, are two-dimensionally formed in the x and y directions at a predetermined arrangement pitch in the shaping aperture array substrate 203. In the case of FIG. 2, 23×23 holes (openings) 22 are formed. Each of the holes 22 is a rectangle (including a square) having the same dimension, shape, and size. Alternatively, each of the holes 22 may be a circle with the same outer diameter. The multiple primary electron beams 20 are formed by letting portions of the electron beam 200 individually pass through a corresponding one of the plurality of holes 22. Next, operations of the image acquisition mechanism 150 in the case of acquiring a secondary electron image will be described below. The primary electron optical system 151 irradiates the substrate 101 with the multiple primary electron beams 20. Specifically, it operates as follows:

The electron beam 200 emitted from the electron gun 201 (emission source) is refracted by the electromagnetic lens 202, and illuminates the whole of the shaping aperture array substrate 203. As shown in FIG. 2, a plurality of holes 22 (openings) are formed in the shaping aperture array substrate 203. The region including all the plurality of holes 22 is irradiated with the electron beam 200. The multiple primary electron beams 20 are formed by letting portions of the electron beam 200 applied to the positions of the plurality of holes 22 individually pass through a corresponding one of the plurality of holes 22 in the shaping aperture array substrate 203.

The formed multiple primary electron beams 20 pass through the large aperture of the beam selection aperture substrate 210, are refracted by the electromagnetic lenses 205 and 206, and, while repeating forming an intermediate image and a crossover, travel to the electromagnetic lens 207 (objective lens) passing through the E×B separator 214 arranged in the intermediate image plane of each beam of the multiple primary electron beams 20.

When the multiple primary electron beams 20 are incident on the electromagnetic lens 207 (objective lens), the electromagnetic lens 207 focuses the multiple primary electron beams 20 onto the substrate 101. The multiple primary electron beams 20 having been focused on the substrate 101 (target object) by the electromagnetic lens 207 are collectively deflected by the deflectors 208 and 209 to irradiate respective beam irradiation positions on the substrate 101. In the case where all of the multiple primary electron beams 20 are collectively deflected by the collective blanking deflector 212, they deviate from the hole in the center of the limiting aperture substrate 213 and all of them are blocked by the limiting aperture substrate 213. By contrast, the multiple primary electron beams 20 which were not deflected by the collective blanking deflector 212 pass through the hole in the center of the limiting aperture substrate 213 as shown in FIG. 1. Blanking control is provided by On/Off of the collective blanking deflector 212, and thus On/Off of the multiple beams is collectively controlled. In this way, the limiting aperture substrate 213 blocks the multiple primary electron beams 20 which were deflected to be in an “Off state” by the collective blanking deflector 212. Then, the multiple primary electron beams 20 for image acquisition are formed by the beams having been made during a period from becoming “beam On” to becoming “beam Off” and having passed through the limiting aperture substrate 213.

When desired positions on the substrate 101 are irradiated with the multiple primary electron beams 20, a flux of secondary electrons (multiple secondary electron beams 300), including reflected electrons, each corresponding to each beam of the multiple primary electron beams 20 is emitted from the substrate 101 due to the irradiation with the multiple primary electron beams 20.

The multiple secondary electron beams 300 emitted from the substrate 101 pass through the electromagnetic lens 207 and travel to the E×B separator 214. The E×B separator 214 includes a plurality of, at least two, magnetic poles each having a coil, and a plurality of, at least two, electrodes (poles). For example, the E×B separator 214 includes four magnetic poles (electromagnetic deflection coils) whose phases are mutually shifted by 90°, and four electrodes (electrostatic deflection electrodes) whose phases are also mutually shifted by 90°. For example, by setting two opposing magnetic poles to be an N pole and an S pole, a directive magnetic field is generated by these plurality of magnetic poles. Also, for example, by applying electrical potentials V whose signs are opposite to each other to the two opposing electrodes, a directive electric field is generated by these plurality of electrodes. Specifically, the E×B separator 214 generates an electric field and a magnetic field to be orthogonal to each other in a plane perpendicular to the traveling direction of the center beam (i.e., trajectory central axis) of the multiple primary electron beams 20. The electric field exerts a force in a fixed direction regardless of traveling direction of electrons. By contrast, the magnetic field exerts a force according to Fleming's left-hand rule. Therefore, the direction of the force acting on (applied to) electrons can be changed depending on the entering (or “traveling”) direction of electrons. With respect to the multiple primary electron beams 20 entering the E×B separator 214 from above, since the forces due to the electric field and the magnetic field cancel each other out, the beams 20 travel straight downward. In contrast, with respect to the multiple secondary electron beams 300 entering the E×B separator 214 from below, since both the forces due to the electric field and the magnetic field are exerted in the same direction, the beams 300 are bent obliquely upward, and separated from the trajectory of the multiple primary electron beams 20.

The multiple secondary electron beams 300 having been bent obliquely upward are further bent by the deflector 218, and projected onto the multi-detector 222 while being refracted by the electromagnetic lens 224. The multi-detector 222 detects the projected multiple secondary electron beams 300 having passed through the openings of the detector aperture array substrate 225. At the detection surface of the multi-detector 222, since each beam of the multiple primary electron beams 20 collides with a detection element corresponding to each secondary electron beam of the multiple secondary electron beams 300, an amplified generation of electrons occurs, and secondary electron image data is generated for each pixel. An intensity signal detected by the multi-detector 222 is output to the detection circuit 106. A sub-irradiation region on the substrate 101, in which the beam concerned itself is located and which is surrounded with the beam's x-direction beam pitch and y-direction beam pitch, is irradiated and scanned by each primary electron beam.

As described above, in order to acquire a secondary electron image, the substrate 101 is irradiated with the multiple primary electron beams 20, and the multi-detector 222 detects the multiple secondary electron beams 300 emitted from the substrate 101 due to the irradiation with the multiple primary electron beams 20. A reflected electron may be included in the detected multiple secondary electron beams 300. Alternatively, it is also acceptable that a reflected electron is separated during moving in the secondary electron optical system 152 not to reach the multi-detector 222. Detection data (measured image data: secondary electron image data: inspection image data) on the secondary electron of each pixel in an individual irradiation region (sub-irradiation region) of each primary electron beam, detected by the multi-detector 222, is output to the detection circuit 106 in the order of measurement. In the detection circuit 106, the detection data in analog form is converted into digital data by an A-D converter (not shown), and stored in the chip pattern memory 123. Then, acquired secondary electron image data (data of a secondary electron image 1) is transmitted to the comparison circuit 108, together with information on each position from the position circuit 107.

In order to acquire an image in the sub-irradiation region of each primary electron beam, a secondary electron beam corresponding to each primary electron beam needs to be detected by a corresponding detection element of the multi-detector 222. Therefore, it is necessary to perform alignment (positioning) between the multiple secondary electron beams 300 corresponding to the multiple primary electron beams 20 and a plurality of detection elements of the multi-detector 222.

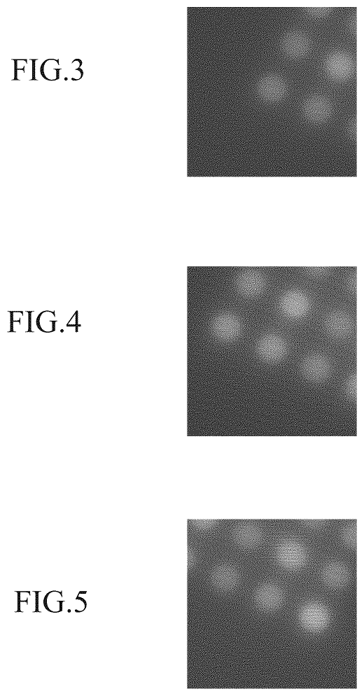

FIG. 3 is an illustration showing an example of a detection image according to a comparative example of the first embodiment.

FIG. 4 is an illustration showing another example of a detection image according to the comparative example of the first embodiment.

FIG. 5 is an illustration showing another example of a detection image according to the comparative example of the first embodiment.

As described above, there exist various beam positional relationships in an acquired image. For example, as shown in the example of FIG. 3, a corner beam can be identified from the image where, clearly, an adjacent beam exists in the diagonally upper right direction with respect to the paper and no beam exists in the opposite direction, and where, clearly, an adjacent beam exists in the diagonally lower right direction and no beam exists in the opposite direction. However, in the examples of FIGS. 4 and 5, although it is known that an adjacent beam exists in the diagonally lower right direction, it is not definitely known whether no beam exists in the opposite direction. Therefore, in the examples of FIGS. 4 and 5, it is difficult to determine whether a corner beam exists in the image or not. Thus, since the positional relationship of beams in an acquired image is various, it is not easy to identify a corner beam. Then, according to the first embodiment, a corner beam can be directly identified from other beams in an obtained image.

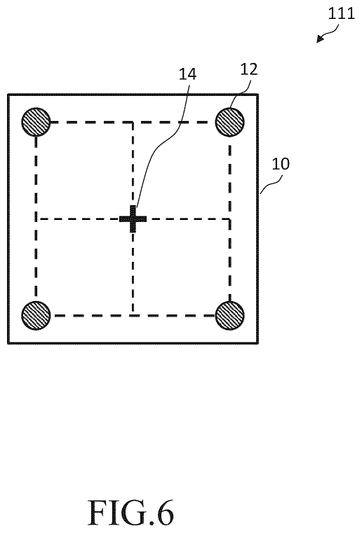

FIG. 6 is an illustration showing an example of a mark member according to the first embodiment. In FIG. 6, the mark member 111 includes a base body 10, a plurality of isolated patterns 12, and an alignment mark 14. The plurality of isolated patterns 12 are formed, on the base body 10, to have the same positional relationship as that of a plurality of irradiation positions, flush in height with the surface of the substrate 101 (target object), of a plurality of primary electron beams having been determined in advance in the multiple primary electron beams 20. A primary electron beam to be detected is determined in advance in the multiple primary electron beams 20. In the case of FIG. 6, four corner beams of the multiple primary electron beams 20 are used as the plurality of primary electron beams having been determined in advance. In other words, four isolated patterns 12 are formed at the same array pitch as that of the four corner beams on the surface of the substrate 101. Preferably, the isolated pattern 12 is circular or rectangular (including square). FIG. 6 shows the case of circular isolated patterns. Each of the plurality of isolated patterns 12 is formed to be larger than each of the multiple primary electron beams 20 on the surface of the substrate 101, and smaller than the pitch between adjacent primary electron beams. Therefore, when the electron beam column 102 applies the multiple primary electron beams 20 to the mark member 111, each isolated pattern 12 is irradiated with one primary electron beam, thereby making it possible to avoid that a plurality of primary electron beams are simultaneously applied to one isolated pattern 12. Each actual irradiation position of the multiple primary electron beams 20 on the substrate 101 may slightly deviate from a design irradiation position due to aberration of the optical system and others. Although the position of each of the four isolated patterns 12 may be determined to be in accordance with an actual measured value, it becomes complicated. Therefore, it is sufficient to form the position of each of the four isolated patterns 12 to be aligned with each design irradiation position.

At the center of the four isolated patterns 12 on the base body 10, there is formed the alignment mark 14. As shown in FIG. 6, preferably, a cross pattern, for example, is used as the alignment mark 14. Similarly to the plurality of isolated patterns 12, the alignment mark 14 is formed at the same height position as that of (being flush in height with) the surface of the substrate 101.

With respect to the base body 10, a material 1 (first material) is used for at least its surface. As the material 1, it is preferable to use silicon (Si), for example. With respect to the plurality of isolated patterns 12, a material 2 (second material) being different from the material 1 is used. As the material 2, one of, for example, nickel (Ni), gold (Au), chromium (Cr), and platinum (Pt) is used. With respect to the alignment mark 14, a material 3 (third material) being different from the materials 1 and 2 is used. As the material 3, titanium (Ti) is used, for example. The emission ratio (yield) of the secondary electron beam to the primary electron beam of the material 1 differs from that of the material 2. Similarly, the emission ratio (yield) of the secondary electron beam to the primary electron beam of the material 1 differs from that of the material 3. The yield of

Si serving as an example of the material 1 is 0.44. The yields of Ni, Au, Cr, and Pt serving as examples of the material 2 are 0.7, 0.94, 1.01, and 1.22 respectively. It is preferable that the yields of the materials 1 and 2 are largely different from each other. The yield of Ti serving as an example of the material 3 is 0.51. It is preferable that the yields of the materials 1 and 3 are different but close to each other.

Now, in the state where the position of the center primary electron beam of the multiple primary electron beams 20 is aligned with the center of the alignment mark 14, when the electron beam column 102 applies the multiple primary electron beams 20 to the mark member 111, four corner beams individually enter the isolated patterns 12. The center primary electron beam is incident on the alignment mark 14. The other primary electron beams are incident on the material 1. Therefore, it is possible to vary the intensity of the secondary electron beam to be generated, among the four corner beams, the center primary electron beam, and the other primary electron beams. In other words, it is possible to make the intensity of four secondary electron beams corresponding to the four corner beams higher than the intensity of a plurality of secondary electron beams corresponding to the other primary electron beams. Furthermore, it is possible to make the intensity of the four secondary electron beams corresponding to the four corner beams higher than the intensity of the center primary electron beam.

In the example described above, the yield of the material 2 of the isolated pattern 12 is higher than that of the material 1 of the base body 10, but it is not limited thereto. It is also preferable that the yield of the material 2 of the isolated pattern 12 is lower than that of the material 1 of the base body 10. For example, as the material 2, beryllium (Be), etc. whose yield is thoroughly lower than that of Si can also preferably be used. Thereby, it is possible to make the intensity of four secondary electron beams corresponding to the four corner beams lower than the intensity of a plurality of secondary electron beams corresponding to the other primary electron beams.

Furthermore, it is possible to make the intensity of four secondary electron beams corresponding to the four corner beams lower than the intensity of the center primary electron beam.

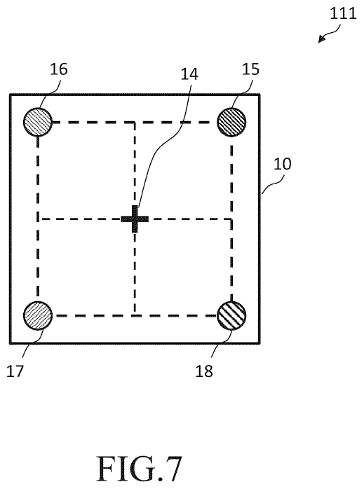

FIG. 7 is an illustration showing another example of the mark member according to the first embodiment. In FIG. 7, the mark member 111 includes the base body 10, a plurality of isolated patterns 15, 16, 17, and 18, and the alignment mark 14. In FIG. 7, similarly to the case of FIG. 6, the material of the plurality of isolated patterns 15, 16, 17, and 18 is different from the material 1. However, in the case of FIG. 7, materials of the plurality of isolated patterns 15, 16, 17, and 18 are different from each other. Alternatively, at least one or more different materials are used for the plurality of isolated patterns 15, 16, 17, and 18. For example, preferably, the plurality of isolated patterns 15, 16, 17, and 18 are respectively formed of Ni, Au, Cr, and Pt. The other configuration is the same as that of FIG. 6. Even in that case, it is possible to make the intensity of four secondary electron beams corresponding to the four corner beams higher than the intensity of a plurality of secondary electron beams corresponding to the other primary electron beams. Furthermore, it is possible to make the intensity of four secondary electron beams corresponding to the four corner beams higher than the intensity of the center primary electron beam.

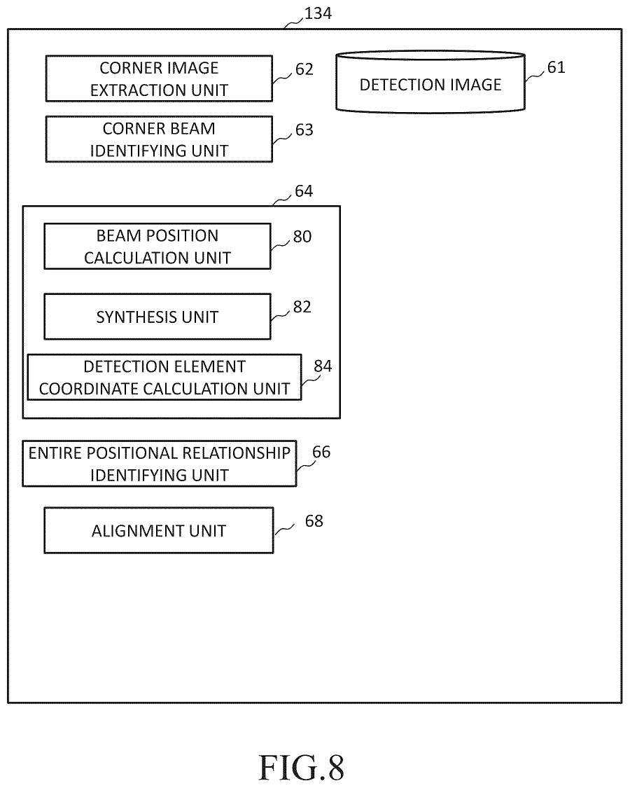

FIG. 8 is a block diagram showing an example of an internal configuration of an alignment circuit according to the first embodiment. As shown in FIG. 8, in the alignment circuit 134, there are arranged a storage device 61 such as a magnetic disk drive for storing a detection image, a corner image extraction unit 62, a corner beam identification unit 63, a corner positional relationship calculation unit 64, an entire positional relationship identification unit 66, and an alignment unit 68.

Furthermore, in the corner positional relationship calculation unit 64, there are arranged a beam position calculation unit 80, a synthesis unit 82, and a detection element coordinate calculation unit 84.

Each of the “units” such as the corner image extraction unit 62, the corner beam identification unit 63, the corner positional relationship calculation unit 64 (the beam position calculation unit 80, the synthesis unit 82, and the detection element coordinate calculation unit 84), the entire positional relationship identification unit 66, and the alignment unit 68 includes processing circuitry. The processing circuitry includes, for example, an electric circuit, a computer, a processor, a circuit board, a quantum circuit, a semiconductor device, or the like. Furthermore, common processing circuitry (the same processing circuitry), or different processing circuitry (separate processing circuitry) may be used for each of the “units”. Input data needed in the corner image extraction unit 62, the corner beam identification unit 63, the corner positional relationship calculation unit 64 (the beam position calculation unit 80, the synthesis unit 82, and the detection element coordinate calculation unit 84), the entire positional relationship identification unit 66, and the alignment unit 68, and calculated results are stored in a memory (not shown) or in the memory 118 each time.

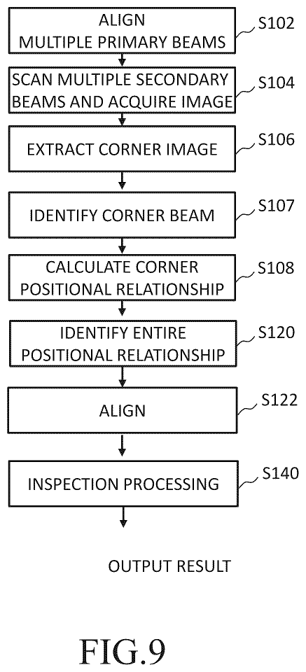

FIG. 9 is a flowchart showing an example of main steps of an inspection method according to the first embodiment. In FIG. 9, the main steps of the inspection method of the first embodiment executes a series of steps: a multiple-primary-beam alignment step (S102), a multiple-secondary-beam scanning and image acquisition step (S104), a corner image extraction step (S106), a corner beam identification step (S107), a corner positional relationship calculation step (S108), an entire positional relationship identification step (S120), an alignment step (S122), and an inspection processing step (S140).

In the multiple-primary-beam alignment step

(S102), alignment of the multiple primary electron beams 20 is performed using the alignment mark 14. Specifically, it operates as follows: First, the stage 105 is moved so that the alignment mark 14 may be located on the trajectory central axis of the multiple primary electron beams 20. The beam selection control circuit 136 controls the drive mechanism 211 to move the beam selection aperture substrate 210 so that the small aperture may be located on the trajectory of the center primary electron beam. Thereby, the beam selection control circuit 136 selectively makes the center primary electron beam of the multiple primary electron beams 20 pass through the small aperture. The other remaining primary electron beams are blocked by the beam selection aperture substrate 210.

Next, the deflector 208 and/or the deflector 209 scan the center primary electron beam over the alignment mark 14 by beam deflection. Then, the multi-detector 222 detects secondary electron beams emitted from the alignment mark 14 and its circumference. Although it is desirable here to detect a secondary electron beam by using the center detection element, in the multi-detector 222, which detects the center secondary electron beam corresponding to the center primary electron beam, another detection element may also be used for detection. The stage 105 is moved so that the image of the alignment mark 14 may be located at the center of an obtained secondary electron image. Alternatively, the deflector 208 and the deflector 209 deflect the center primary electron beam so that the image of the alignment mark 14 may be located at the center of the secondary electron image obtained. Thereby, the multiple primary electron beams 20 can be aligned with the mark member 111.

After the alignment, the beam selection control circuit 136 controls the drive mechanism 211 to move the beam selection aperture substrate 210 so that the large aperture may be located on the trajectory of the multiple primary electron beams 20. Thereby, all of the multiple primary electron beams 20 can pass through the large aperture.

In the multiple-secondary-beam scanning and image acquisition step (S104), in the state where alignment of the multiple primary electron beams 20 has been performed using the alignment mark 14, the primary electron optical system 151 irradiates the mark member 111 with the multiple primary electron beams 20. Specifically, it operates as follows: The image acquisition mechanism 150 applies the multiple primary electron beams 20 onto the stage 105 in a stopped state. At this time, the deflectors 208 and 209 align the center of the multiple primary electron beams 20 with the position of the trajectory central axis of the multiple primary electron beams. If, without being deflected, the center of the multiple primary electron beams 20 is at the trajectory central axis of the multiple primary electron beams 20, it is acceptable not to provide deflection. Thereby, the scanning center position of the scanning range of each primary electron beam is continuously irradiated with each primary electron beam concerned.

The deflector 226 (deflector in the secondary electron optical system) scans the multiple secondary electron beams 300, emitted from the mark member 111 due to irradiation of the multiple primary electron beams 20, over a plurality of detection elements of the multi-detector 222. Specifically, it operates as follows: The multiple secondary electron beams 300 emitted from the mark member 111 are projected onto the multi-detector 222 by the secondary electron optical system 152 through the detector aperture array substrate 225. In this state, the deflector 226 scans the secondary beam scanning range which has been set in advance for the multiple secondary electron beams 300.

The multi-detector 222 detects the multiple secondary electron beams 300 emitted from the mark member 111 due to irradiation of the mark member 111 with the multiple primary electron beams 20, and outputs detected image data. In other words, the multi-detector 222 detects the multiple secondary electron beams 300 by a plurality of detection elements (first detection element) arrayed in a grid. Thereby, each detection element acquires an aperture image of the detector aperture array substrate 225. The multi-detector 222 detects a plurality of beams including at least a corner beam at a corner among the multiple secondary electron beams 300.

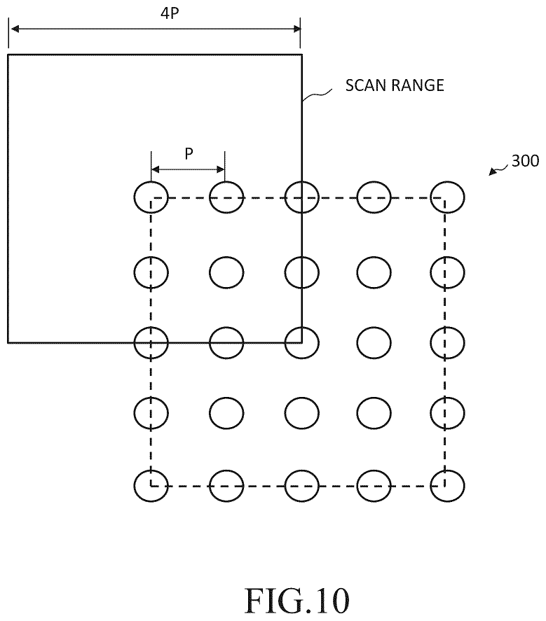

FIG. 10 is an illustration showing an example of a secondary electron beam array according to the first embodiment. FIG. 10 shows the case of the multiple secondary electron beams 300 of 5×5 beams, for example. Even in view of an image (dotted line range) of beams close to the center secondary electron beam shown in FIG. 10, it is difficult to distinguish (discriminate) a positional relationship concerning which beam in the image corresponds to which position. In contrast, according to an image of beams at the four corners, (e.g., 2×2 beams at the upper left corner), it is possible to distinguish a corner beam actually at the corner among the beams. Therefore, the positional relationship concerning the beams can be obtained. When the positional relationship of beams with respect to the image is known, the positional relationship between detection elements having been used for acquiring the image and the beams can be obtained. When the deflector 226 collectively performs scanning with the multiple secondary electron beams 300, it scans the scanning range being four or more times the beam pitch P of the multiple secondary electron beams 300 as shown in FIG. 10. FIG. 10 shows a scanning range, by a solid line, being four times the beam pitch P of the multiple secondary electron beams 300, centering on the left corner beam. Thereby, in the case of scanning with the multiple secondary electron beams 300, 2×2 beams including a corner beam can be contained in each scan range of 2×2 detection elements corresponding to the 2×2 beams including the corner beam.

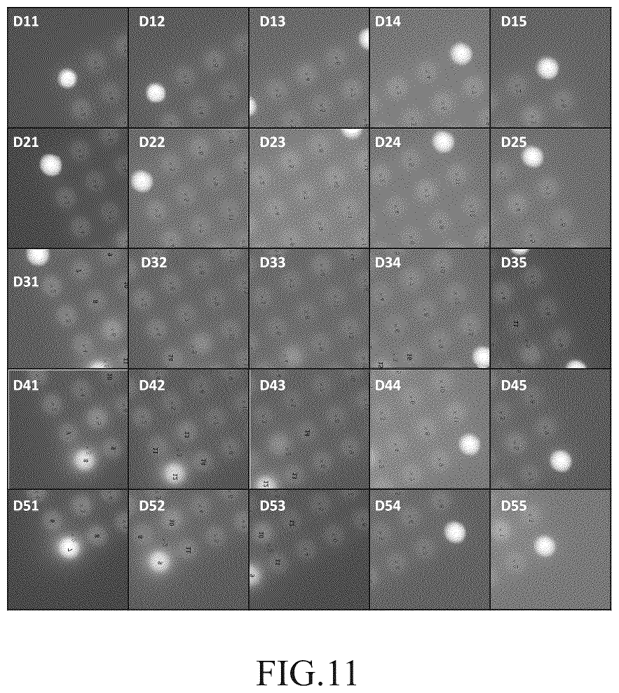

FIG. 11 is an illustration showing examples of images each obtained by each detection element according to the first embodiment. FIG. 11 shows examples of aperture images imaged by 5×5 detection elements D11 to D55 corresponding to the multiple secondary electron beams 300 of 5×5 beams. Each detection element acquires images of a plurality of secondary electron beams passing over the detection element concerned due to a scan operation of the multiple secondary electron beams 300. Actually, beams having passed through the openings in the detector aperture array substrate 225 are detected. Therefore, a plurality of aperture images are detected by each detection element.

Detection data on a secondary electron detected by each detection element is output to the detection circuit 106 in the order of measurement. In the detection circuit 106, the detection data in analog form is converted into digital data by an A-D converter (not shown), and stored in the chip pattern memory 123. Then, the obtained secondary electron image data is output to the alignment circuit 134. In the alignment circuit 134, the secondary electron image data (detected image) is stored in the storage device 61.

In the corner image extraction step (S106), the corner image extraction unit 62 extracts corner images from images of all the detection elements.

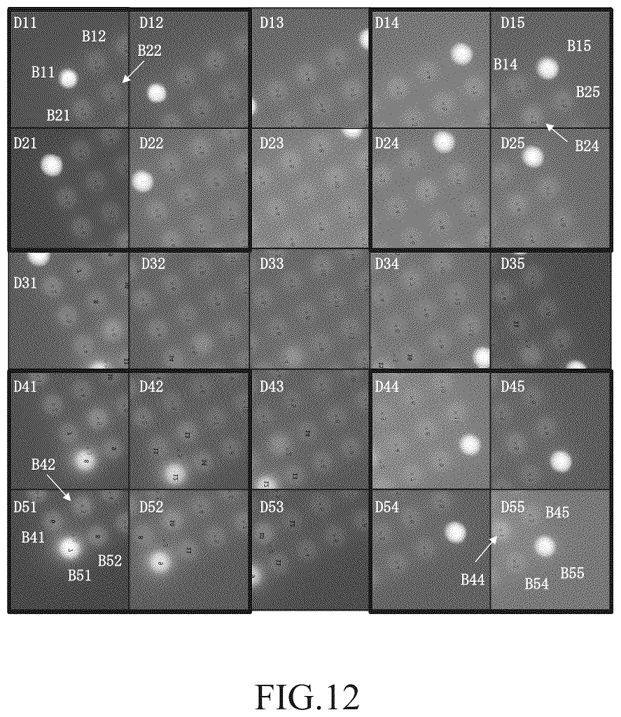

FIG. 12 is an illustration showing corner part images in image examples each acquired by each detection element according to the first embodiment. FIG. 12 shows, similarly to FIG. 11, images imaged by the 5×5 detection elements D11 to D55. In FIG. 12, images acquired by 2×2 detection elements D11, D12, D21, and D22 are shown including one of corner part images which is imaged by the detection element D11. Similarly, images acquired by 2×2 adjacent detection elements D14, D15, D24, and D25 are shown including one of corner part images which is imaged by the detection element D15. Similarly, images acquired by 2×2 detection elements D41, D42, D51, and D52 are shown including one of corner part images which is imaged by the detection element D51. Similarly, images acquired by 2×2 detection elements D44, D45, D54, and D55 are shown including one of corner part images which is imaged by the detection element D55.

The 2×2 detection elements D11, D12, D21, and D22, including the detection element D11, detect aperture images of 2×2 adjacent secondary electron beams including a corner beam corresponding to the detection element D11. Similarly, the 2×2 adjacent detection elements D14, D15, D24, and D25, including the detection element D15, detect aperture images of 2×2 secondary electron beams including a corner beam corresponding to the detection element D15. Similarly, the 2×2 detection elements D41, D42, D51, and D52, including the detection element D51, detect aperture images of 2×2 adjacent secondary electron beams including a corner beam corresponding to the detection element D15. Similarly, the 2×2 detection elements D44, D45, D54, and D55, including the detection element D55, detect aperture images of 2×2 adjacent secondary electron beams including a corner beam corresponding to the detection element D55.

Now, images acquired by the 2×2 detection elements D11, D12, D21, and D22 are extracted, for example.

In the corner beam identification step (S107), using the detected image of the multiple secondary electron beams 300, the corner beam identification unit 63 (identification circuit) identifies four corner beams (a plurality of beams having been determined in advance), based on a difference between intensities in the image. Specifically, the corner beam identification unit 63 identifies that, in the image obtained by the detection element D11, the aperture image of the secondary electron beam whose brightness is higher than those of the other aperture images of the secondary electron beams is the aperture image of the corner beam B11. Similarly, with respect to images obtained by the detection elements D12, D21, and D22, the corner beam identification unit 63 identifies that the aperture image of the secondary electron beam whose brightness is higher than those of the other aperture images of the secondary electron beams is the aperture image of the corner beam B11.

As described above, since, in an obtained image, it is possible to make the intensity of the aperture image of the corner beam higher (or lower) than the intensities of the aperture images of the other secondary electron beams, a desired beam (in this case, corner beam B11) can be easily identified.

Similarly, in the images obtained by 2×2 adjacent detection elements D14, D15, D24, and D25 including the detection element D15, the corner beam identification unit 63 identifies that the aperture image of the secondary electron beam whose brightness is higher than those of the other aperture images of the secondary electron beams is the aperture image of the corner beam B15.

Similarly, in the images obtained by 2×2 detection elements D41, D42, D51, and D52 including the detection element D51, the corner beam identification unit 63 identifies that the aperture image of the secondary electron beam whose brightness is higher than those of the other aperture images of the secondary electron beams is the aperture image of the corner beam B51.

Similarly, in the images obtained by 2×2 detection elements D44, D45, D54, and D55 including the detection element D55, the corner beam identification unit 63 identifies that the aperture image of the secondary electron beam whose brightness is higher than those of the other aperture images of the secondary electron beams is the aperture image of the corner beam B55.

There may be a case where no corner beam exists in an image. As a cause of this, the beam pitch of the multiple secondary electron beams 300 may be too large. In that case, the beam pitch is adjusted, and it starts again from the multiple-secondary-beam scanning and image acquisition step (S104).

Furthermore, there may be a case where no images of two or more corner parts in four corner parts can be obtained. As a cause of this, the beam axis of the multiple secondary electron beams 300 may be largely misaligned. In that case, the beam axis is adjusted, and it starts again from the multiple-secondary-beam scanning and image acquisition step (S104).

Thus, as described above, according to the first embodiment, by forming the mark member 111 such that the intensity of a desired secondary electron beam is different from the intensities of other secondary electron beams, the desired secondary electron beam (here, e.g., corner beam) can be easily identified from the obtained image regardless of a positional relationship among a plurality of beams in the obtained image.

Next, using the identified corner beam, the positional relationship between the multiple secondary electron beams 300 and a plurality of detection elements of the multi-detector 222 is calculated. It is specifically described below.

In the corner positional relationship calculation step (S108), the corner positional relationship calculation unit 64 (positional relationship calculation unit) calculates a positional relationship between a plurality of secondary electron beams including a corner beam and a plurality of detection elements (second detection element) which have detected a plurality of secondary electron beams including the corner beam in a plurality of detection elements. Specifically, it operates as follows:

The beam position calculation unit 80 calculates, for each extracted image, positions of 2×2 beams including a corner beam.

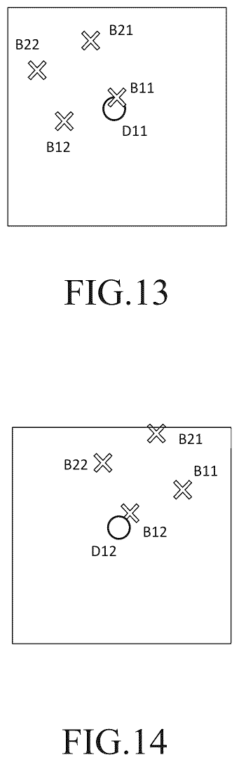

FIG. 13 is an illustration showing a result of calculating a relative positional relationship between the detection element D11 and each of the beams B11, B12, B21, and B22, based on the output image of the detection element D11 in FIG. 12. The output image of the detection element D11 in FIG. 12 shows the positional relationship, in the case of scanning the beams B11, B12, B21, and B22, between the scanning center of each of the beams B11, B12, B21, and B22 and the detection element D11. Therefore, reversely, viewed from the detection element D11, the position of each of the beams B11, B12, B21, and B22 can be obtained. This result is shown in FIG. 13. For example, in the output image of the detection element D11 of FIG. 12, the beam B12 is at the upper right relative to the center. This means that the detection element D11 is at the upper right viewed from the scanning center of the beam B12. Viewed this from the detection element D11, the beam B12 is at the lower left. Therefore, in FIG. 13, the beam B12 is at the lower left relative to the center.

Similarly, for example, in the output image of the detection element D11 of FIG. 12, the beam B11 is at the slightly lower left relative to the center. This means that the detection element D11 is at the slightly lower left viewed from the scanning center of the beam B11. Viewed this from the detection element D11, the beam B11 is at the slightly upper right. Therefore, in FIG. 13, the beam B11 is at the slightly upper right relative to the center.

Similarly, for example, in the output image of the detection element D11 of FIG. 12, the beam B21 is at the lower, slightly right relative to the center. This means that the detection element D11 is at the lower, slightly right viewed from the scanning center of the beam B21. Viewed this from the detection element D11, the beam B21 is at the upper, slightly left. Therefore, in FIG. 13, the beam B21 is at the upper, slightly left relative to the center.

Similarly, for example, in the output image of the detection element D11 of FIG. 12, the beam B22 is at the lower right relative to the center. This means that the detection element D11 is at the lower right viewed from the scanning center of the beam B22. Viewed this from the detection element D11, the beam B22 is at the upper left. Therefore, in FIG. 13, the beam B22 is at the upper left relative to the center.

FIG. 14 is an illustration showing a result of calculating a relative positional relationship between the detection element D12 and each of the beams B11, B12, B21, and B22, based on the output image of the detection element D12 in FIG. 12. The output image of the detection element D12 in FIG. 12 shows the positional relationship, in the case of scanning the beams B11, B12, B21, and B22, between the scanning center of each of the beams B11, B12, B21, and B22 and the detection element D12. Therefore, reversely, viewed from the detection element D12, the position of each of the beams B11, B12, B21, and B22 can be obtained. This result is shown in FIG. 14. For example, in the output image of the detection element D12 of FIG. 12, the beam B12 is at the slightly lower left relative to the center. This means that the detection element D12 is at the slightly lower left viewed from the scanning center of the beam B12. Viewed this from the detection element D12, the beam B12 is at the slightly upper right. Therefore, in FIG. 14, the beam B12 is at the slightly upper right relative to the center.

Similarly, for example, in the output image of the detection element D12 of FIG. 12, the beam B11 is at the lower left relative to the center. This means that the detection element D12 is at the lower left viewed from the scanning center of the beam B11. Viewed this from the detection element D12, the beam B11 is at the upper right. Therefore, in FIG. 14, the beam B11 is at the upper right relative to the center.

Similarly, for example, in the output image of the detection element D12 of FIG. 12, the beam B21 is at the lower, slightly left, relative to the center. This means that the detection element D12 is at the lower, slightly left, viewed from the scanning center of the beam B21. Viewed this from the detection element D12, the beam B21 is at the upper, slightly right. Therefore, in FIG. 14, the beam B21 is at the upper, slightly right, relative to the center.

Similarly, for example, in the output image of the detection element D12 of FIG. 12, the beam B22 is at the lower right relative to the center. This means that the detection element D12 is at the lower right viewed from the scanning center of the beam B22. Viewed this from the detection element D12, the beam B22 is at the upper left. Therefore, in FIG. 14, the beam B22 is at the upper left relative to the center.

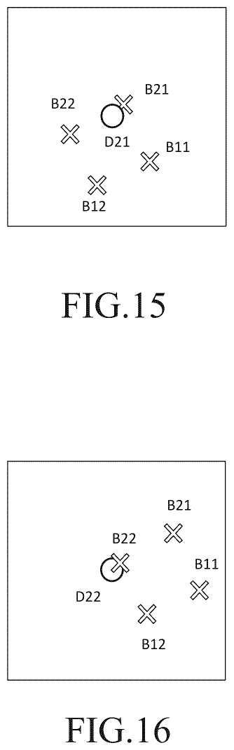

FIG. 15 is an illustration showing a result of calculating a relative positional relationship between the detection element D21 and each of the beams B11, B12, B21, and B22, based on the output image of the detection element D21 in FIG. 12. The output image of the detection element D21 in FIG. 12 shows the positional relationship, in the case of scanning the beams B11, B12, B21, and B22, between the scanning center of each of the beams B11, B12, B21, and B22 and the detection element D21. Therefore, reversely, viewed from the detection element D21, the position of each of the beams B11, B12, B21, and B22 can be obtained. This result is shown in FIG. 15. For example, in the output image of the detection element D21 of FIG. 12, the beam B12 is at the upper, slightly right, relative to the center. This means that the detection element D21 is at the upper, slightly right, viewed from the scanning center of the beam B12. Viewed this from the detection element D21, the beam B12 is at the lower, slightly left. Therefore, in FIG. 15, the beam B12 is at the lower, slightly left, relative to the center.

Similarly, for example, in the output image of the detection element D21 of FIG. 12, the beam B11 is at the upper left relative to the center. This means that the detection element D21 is at the upper left viewed from the scanning center of the beam B11. Viewed this from the detection element D21, the beam B11 is at the lower right. Therefore, in FIG. 15, the beam B11 is at the lower right relative to the center.

Similarly, for example, in the output image of the detection element D21 of FIG. 12, the beam B21 is at the slightly lower left relative to the center. This means that the detection element D21 is at the slightly lower left viewed from the scanning center of the beam B21. Viewed this from the detection element D21, the beam B21 is at the slightly upper right. Therefore, in FIG. 15, the beam B21 is at the slightly upper right relative to the center.

Similarly, for example, in the output image of the detection element D21 of FIG. 12, the beam B22 is at the right, slightly upper, relative to the center. This means that the detection element D21 is at the right, slightly upper, viewed from the scanning center of the beam B22. Viewed this from the detection element D21, the beam B22 is at the left, slightly lower. Therefore, in FIG. 15, the beam B22 is at the left, slightly lower, relative to the center.

FIG. 16 is an illustration showing a result of calculating a relative positional relationship between the detection element D22 and each of the beams B11, B12, B21, and B22, based on the output image of the detection element D22 in FIG. 12. The output image of the detection element D22 in FIG. 12 shows the positional relationship, in the case of scanning the beams B11, B12, B21, and B22, between the scanning center of each of the beams B11, B12, B21, and B22 and the detection element D22. Therefore, reversely, viewed from the detection element D22, the position of each of the beams B11, B12, B21, and B22 can be obtained. This result is shown in FIG. 16. For example, in the output image of the detection element D22 of FIG. 12, the beam B12 is at the upper left relative to the center. This means that the detection element D22 is at the upper left viewed from the scanning center of the beam B12. Viewed this from the detection element D22, the beam B12 is at the lower right. Therefore, in FIG. 16, the beam B12 is at the lower right relative to the center.

Similarly, for example, in the output image of the detection element D22 of FIG. 12, the beam B11 is at the left, slightly upper, relative to the center. This means that the detection element D22 is at the left, slightly upper, viewed from the scanning center of the beam B11. Viewed this from the detection element D22, the beam B11 is at the right, slightly lower. Therefore, in FIG. 16, the beam B11 is at the right, slightly lower, relative to the center.

Similarly, for example, in the output image of the detection element D22 of FIG. 12, the beam B21 is at the lower left relative to the center. This means that the detection element D22 is at the lower left viewed from the scanning center of the beam B21. Viewed this from the detection element D22, the beam B21 is at the upper right. Therefore, in FIG. 16, the beam B21 is at the upper right relative to the center.

Similarly, for example, in the output image of the detection element D22 of FIG. 12, the beam B22 is at the slightly lower left relative to the center. This means that the detection element D22 is at the slightly lower left viewed from the scanning center of the beam B22. Viewed this from the detection element D22, the beam B22 is at the slightly upper right. Therefore, in FIG. 16, the beam B22 is at the slightly upper right relative to the center.

Next, the synthesis unit 82 synthesizes the positional relation between respective detection elements and the respective beam positions calculated from the four images at the corner.

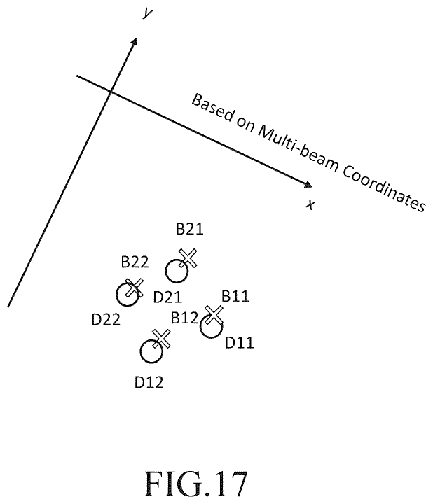

FIG. 17 is an illustration showing an example of

relation after synthesis between the position of each detection element and that of each beam according to the first embodiment. The same 2×2 beams B11, B12, B21, and B22 are used in every positional relationship in FIGS. 13 to 16. Therefore, the positional relationship among the 2×2 beams B11, B12, B21, and B22 is the same in FIGS. 13 to 16. Then, the positions of respective detection elements are synthesized so that the positions of the same beams of the 2×2 beams B11, B12, B21, and B22 in FIGS. 13 to 16 including the corner beam B11 may be aligned each other. FIG. 17 shows, based on the coordinates of the multiple secondary electron beams 300 (which is a secondary coordinate system), a relation between the position of each of the detection elements D11, D12, D21, and D22 and that of each of the beams B11, B12, B21, and B22 at a corner. The secondary coordinate system is a coordinate system centering on the center position of the multiple secondary electron beams 300. Therefore, coordinates of each secondary electron beam of the multiple secondary electron beams 300 can be identified in the secondary coordinate system. Accordingly, if the positional relationship with each beam is known, coordinates of the detection element in the secondary coordinate system can be identified.

Furthermore, the positional relationship is similarly calculated with respect to other corners. Specifically, the relation between the position of each of the detection elements D14, D15, D24, and D25 and that of each of the beams B14, B15, B24, and B25 is calculated. Similarly, the relation between the position of each of the detection elements D41, D42, D51, and D52 and that of each of the beams B41, B42, B51 and B52 is calculated. Similarly, the relation between the position of each of the detection elements D44, D45, D54, and D55 and that of each of the beams B44, B45, B54, and B55 is calculated.

In the entire positional relationship identification step (S120), the entire positional relationship identification unit 66 identifies an entire positional relationship between the multiple secondary electron beams 300 and the entire detection elements.

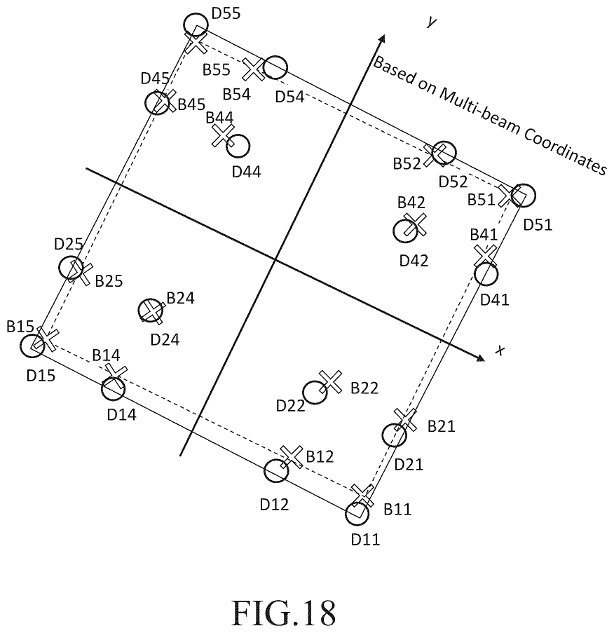

FIG. 18 is an illustration showing an example of an entire positional relationship according to the first embodiment. Since positional relationships at four corners have been calculated, the relationships are combined. Furthermore, since the arrangement positional relationship and the arrangement pitch of the 5×5 detection elements D11 to D55 of the multi-detector 222 are known in advance, with defining 2×2 detection elements calculated at each corner as one set, four sets for four corners are individually applied to a corresponding arrangement position. Thereby, as shown in FIG. 18, the position of the whole of the 5×5 multiple secondary electron beams 300 with respect to the position of the whole of the 5×5 detection elements can be identified. Therefore, it is possible to identify a positional relationship among the 5×5 detection elements D11 to D55 in the secondary coordinate system. In connection with this, positions of sixteen beams are also identified.

In the alignment step (S122), the alignment unit 68 performs alignment, by rotation and parallel displacement, between 5×5 multiple secondary electron beams 300 and 5×5 detection elements D11 to D55 of the multi-detector 222. Specifically, the detector stage control circuit 130 controls the drive mechanism 132 to rotate the rotary stage 227. By this, the rotary stage 227 rotates the multi-detector 222. Furthermore, the detector stage control circuit 130 controls the drive mechanism 132 to move the X-Y stage 228 (moving mechanism). By this, the X-Y stage 228 moves the multi-detector 222 relatively to the multiple secondary electron beams 300. Specifically, the multi-detector 222 is displaced in parallel. For example, the multi-detector 222 is moved mechanically.

By the operations described above, a plurality of detection elements D11 to D55 of the multi-detector 222 can be aligned with the multiple secondary electron beams B11 to B55.

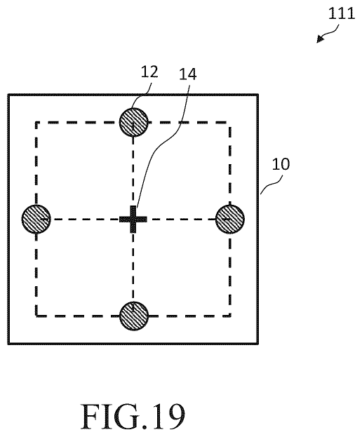

FIG. 19 is an illustration showing an example of a mark member according to a modified example of the first embodiment. In FIG. 19, the mark member 111 includes the base body 10, a plurality of isolated patterns 12, and the alignment mark 14. FIG. 19 shows the case where each of a plurality of isolated patterns 12 is formed to have the same positional relationship as that of the irradiation position of a primary electron beam on each of the four outer peripheral sides of the multiple primary electron beams 20 on the surface of the substrate 101. A primary electron beam to be detected in the multiple primary electron beams 20 is determined in advance. In the example of FIG. 19, the isolated pattern 12 is individually formed to have the same positional relationship as that of the irradiation position of the primary electron beam at the center of each peripheral side. Other configuration is the same as that of FIG. 6. Similarly to the case of FIG. 6, each actual irradiation position of the multiple primary electron beams 20 on the substrate 101 may slightly deviate from a design irradiation position due to aberration of the optical system and others. Although the position of each of the four isolated patterns 12 may be determined to be in accordance with an actual measured value, it becomes complicated. Therefore, it is sufficient to form (determine) the position of each of the four isolated patterns 12 to be aligned with each design irradiation position.

Now, in the state where the position of the center primary electron beam of the multiple primary electron beams 20 is aligned with the center of the alignment mark 14, when the electron beam column 102 applies the multiple primary electron beams 20 to the mark member 111, each of the four primary electron beams at the center of each of the four outer peripheral sides is incident on each of the isolated patterns 12. The center primary electron beam is incident on the alignment mark 14. The other primary electron beams enter the material 1. Therefore, it is possible to vary the intensity of the secondary electron beam to be generated, among the four primary electron beams individually at the centers of the four outer peripheral sides, the center primary electron beam, and the other primary electron beams. In other words, the intensity of each of the four secondary electron beams individually corresponding to each of the four primary electron beams at the center of each of the four outer peripheral sides can be made higher than the intensity of a plurality of secondary electron beams corresponding to the other primary electron beams. Furthermore, the intensity of each of the four secondary electron beams corresponding to the four primary electron beams at the centers of the four outer peripheral sides can be made higher than the intensity of the center primary electron beam.

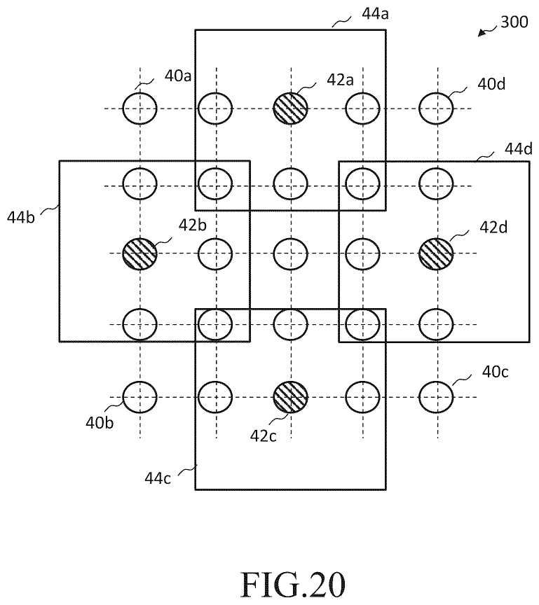

FIG. 20 is an illustration describing a method for identifying a beam positional relationship according to a modified example of the first embodiment. FIG. 20 shows an image 44a of, for example, 2×3 beams including a primary electron beam 42a at the center of the upper peripheral side of the four peripheral sides of the multiple primary electron beams 20. Similarly, FIG. 20 shows an image 44b of, for example, 2×3 beams including a primary electron beam 42b at the center of the left peripheral side of the four peripheral sides of the multiple primary electron beams 20. Similarly, FIG. 20 shows an image 44c of, for example, 2×3 beams including a primary electron beam 42c at the center of the lower peripheral side of the four peripheral sides of the multiple primary electron beams 20. Similarly, FIG. 20 shows an image 44d of, for example, 2×3 beams including a primary electron beam 42d at the center of the right peripheral side of the four peripheral sides of the multiple primary electron beams 20. With respect to the primary electron beams 42a, 42b, 42c, and 42d each at the center of each of the peripheral sides, since the intensity of each of their secondary electron beams is different as described above, it can be easily identified from each image. Even if the corner position is not obtained, since the positional relationship (arrangement) among the four sets of the detected 2×3 detection elements is known in advance (refer to dotted lines), the whole of the positional relationship can be obtained by applying this arrangement. Simultaneously, the beam position is also identified. Therefore, an alignment between the multiple secondary electron beams 300 and each detection element of the multi-detector 222 can be performed.

FIG. 19 shows the case where a plurality of isolated patterns 12 are formed to have the same positional relationship as that of the irradiation position of a primary electron beam at the center of each of the four outer peripheral sides of the multiple primary electron beams 20, but it is not limited thereto. It is also sufficient that each of a plurality of isolated patterns 12 is formed to be aligned with the irradiation position of each primary electron beam which is not at the center of each of the four outer peripheral sides.

In the inspection processing step (S140), the substrate 101 is inspected using the inspection apparatus 100 for which alignment has been performed.

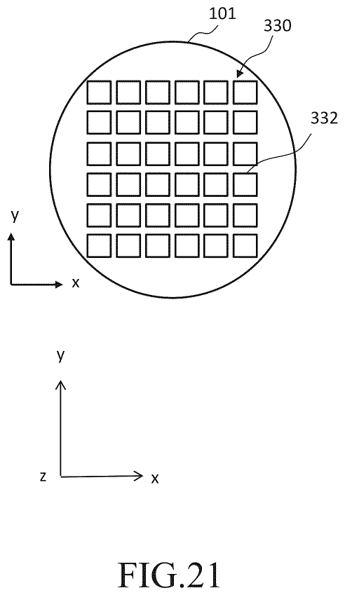

FIG. 21 is an illustration showing an example of a plurality of chip regions formed on a semiconductor substrate, according to the first embodiment. In FIG. 21, in the case of the substrate 101 being a semiconductor substrate (wafer), a plurality of chips (wafer dies) 332 are formed in a two-dimensional array in an inspection region 330 of the semiconductor substrate (wafer). A mask pattern for one chip formed on an exposure mask substrate is reduced to, for example, ¼, and exposed/transferred onto each chip 332 by an exposure device such as a stepper (not shown). The mask pattern for one chip is generally composed of a plurality of figure patterns.

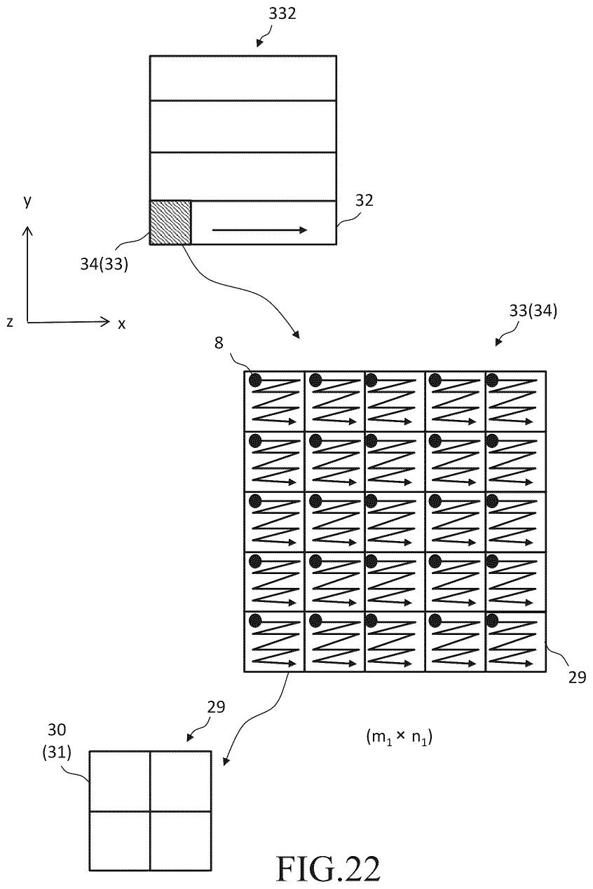

FIG. 22 is an illustration describing inspection processing according to the first embodiment. As shown in FIG. 22, the region of each chip 332 is divided, for example, in the y direction into a plurality of stripe regions 32 by a predetermined width. The scan operation by the image acquisition mechanism 150 is carried out for each stripe region 32, for example. The operation of scanning the stripe region 32 advances relatively in the x direction while the stage 105 is moved in the −x direction, for example. Each stripe region 32 is divided in the longitudinal direction into a plurality of rectangular (including square) regions 33. Beam application to a target rectangular region 33 is achieved by collectively deflecting all the multiple primary electron beams 20 by the deflectors 208 and 209.

The case of FIG. 22 shows the multiple primary electron beams 20 of 5 rows×5 columns, for example. The size of an irradiation region 34 which can be irradiated by one irradiation with the multiple primary electron beams 20 is defined by (x direction size obtained by multiplying an x-direction beam pitch by the number of x-direction beams of the multiple primary electron beams 20 on the substrate 101)×(y direction size obtained by multiplying a y-direction beam pitch by the number of y-direction beams of the multiple primary electron beams 20 on the substrate 101). The irradiation region 34 serves as a field of view of the multiple primary electron beams 20. A sub-irradiation region 29, which is surrounded by the x-direction beam pitch and the y-direction beam pitch and in which the beam concerned itself is located, is irradiated and scanned (scan operation) with each primary electron beam 8 of the multiple primary electron beams 20. Each primary electron beam 8 is associated with any one of the sub-irradiation regions 29 which are different from each other. At the time of each shot, each primary electron beam 8 is applied to the same position in the associated sub-irradiation region 29. The primary electron beam 8 is moved in the sub-irradiation region 29 by collective deflection of all the multiple primary electron beams 20 by the deflectors 208 and 209. By repeating this operation, the inside of one sub-irradiation region 29 is irradiated, in order, with one primary electron beam 8.

Preferably, the width of each stripe region 32 is set to be the same as the y-direction size of the irradiation region 34, or to be the size reduced by the width of the scanning margin. In the case of FIG. 22, the irradiation region 34 and the rectangular region 33 are of the same size. However, it is not limited thereto. The irradiation region 34 may be smaller than the rectangular region 33, or larger than it. Using each primary electron beam 8 of the multiple primary electron beams 20, the sub-irradiation region 29 in which the primary electron beam 8 concerned itself is located is irradiated and scanned (scan operation) by the primary electron beam 8 concerned. Then, when scanning of one sub-irradiation region 29 is completed, the irradiation position is moved to an adjacent rectangular region 33 in the same stripe region 32 by collective deflection of all the multiple primary electron beams 20 by the deflectors 208 and 209. repeating this operation, the inside of the stripe region 32 is irradiated in order. After completing scanning of one stripe region 32, the irradiation region 34 is moved to the next stripe region 32 by movement of the stage 105 and/or by collective deflection of all of the multiple primary electron beams 20 by the deflectors 208 and 209. As described above, by irradiation with each primary electron beam 8, the scan operation per sub-irradiation region 29 and acquisition of a secondary electron image are performed. By combining these secondary electron images of respective sub-irradiation regions 29, a secondary electron image of the rectangular region 33, a secondary electron image of the stripe region 32, or a secondary electron image of the chip 332 is configured. When an image comparison is actually performed, the sub-irradiation region 29 in each rectangular region 33 is further divided into a plurality of frame regions 30, and then, a comparison is performed with respect to a frame image 31 of each frame region 30. FIG. 22 shows the case of dividing the sub-irradiation region 29, which is scanned with one primary electron beam 8, into four frame regions 30 by halving it in the x and y directions, for example.

In the case of applying the multiple primary electron beams 20 to the substrate 101 while the stage 105 is continuously moving, the deflectors 208 and 209 execute a tracking operation by performing collective deflection so that the irradiation position of the multiple primary electron beams 20 may follow the movement of the stage 105. Therefore, the emission position of the multiple secondary electron beams 300 changes every second with respect to the trajectory central axis of the multiple primary electron beams 20. Similarly, in the case of scanning the sub-irradiation region 29, the emission position of each secondary electron beam changes every second inside the sub-irradiation region 29. The deflector 226 collectively deflects the multiple secondary electron beams 300 so that each secondary electron beam whose emission position has changed may be applied to a corresponding detection region of the multi-detector 222.

As described above, the image acquisition mechanism 150 proceeds with scanning of each stripe region 32. An image (secondary electron image) to be used for inspection is acquired by irradiating the inspection substrate 101 on the stage 105 with the multiple primary electron beams 20, and detecting, by the multi-detector 222, the multiple secondary electron beams 300 emitted from the substrate 101 due to the irradiation with the multiple primary electron beams 20. A reflected electron may be included in detected multiple secondary electron beams 300. Alternatively, a reflected electron may be separated during moving in the secondary electron optical system 152 not to reach the multi-detector 222. Detection data (measured image data: secondary electron image data: inspection image data) on the secondary electron of each pixel in each sub-irradiation region 29, detected by the multi-detector 222, is output to the detection circuit 106 in order of measurement. In the detection circuit 106, the detection data in analog form is converted into digital data by an A-D converter (not shown), and stored in the chip pattern memory 123. Then, acquired measured image data is transmitted to the comparison circuit 108, together with information on each position from the position circuit 107.

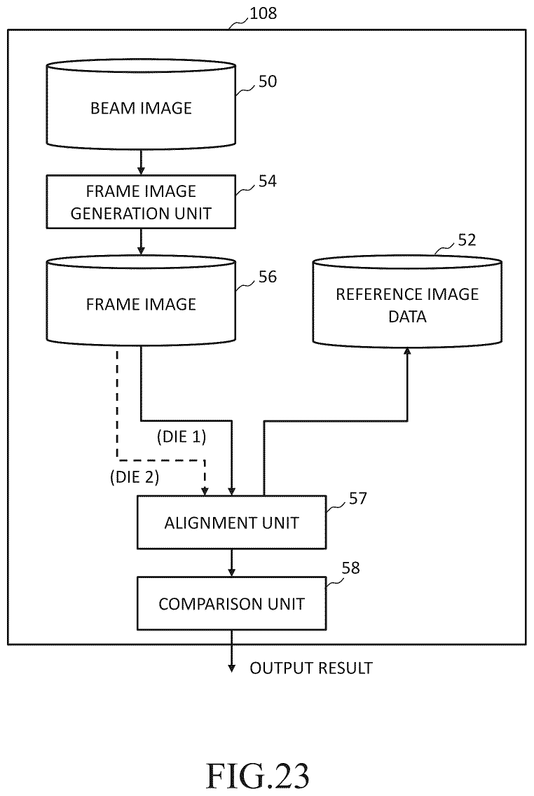

FIG. 23 is a diagram showing an example of an internal configuration of a comparison circuit according to the first embodiment. In FIG. 23, storage devices 50, 52 and 56 such as magnetic disk drives, a frame image generation unit 54, an alignment unit 57, and a comparison unit 58 are arranged in the comparison circuit 108. Each of the “units” such as the frame image generation unit 54, the alignment unit 57 and the comparison unit 58 includes processing circuitry. The processing circuitry includes an electric circuit, a computer, a processor, a circuit board, a quantum circuit, a semiconductor device, or the like. Further, common processing circuitry (same processing circuitry), or different processing circuitry (separate processing circuitry) may be used for each of the “units”. Input data needed in the frame image generation unit 54, the alignment unit 57 and the comparison unit 58, or a calculated result is stored in a memory (not shown) or in the memory 118 each time.

Measured image data (beam image) transmitted into the comparison circuit 108 is stored in the storage device 50.

The frame image generation unit 54 generates the frame image 31 of each of a plurality of frame regions 30 by further dividing image data of the sub-irradiation region 29 acquired by scanning with each primary electron beam 8. The frame region 30 is used as a unit region of an inspection image to be inspected. In order to prevent missing an image, it is preferable that the margin region of each frame region 30 overlaps with each other. The generated frame image 31 is stored in the storage device 56.

The reference image generation circuit 112 generates, for each frame region 30, a reference image corresponding to the frame image 31, based on design data serving as a basis of a plurality of figure patterns formed on the substrate 101. Specifically, it operates as follows: First, design pattern data is read from the storage device 109 through the control computer 110, and each figure pattern defined by the read design pattern data is converted into image data in binary or multiple values.

As described above, basic figures defined by the design pattern data are, for example, rectangles (including squares) and triangles. For example, there is stored figure data which defines the shape, size, position, and the like of each pattern figure by using information, such as coordinates (x, y) of the reference position of the figure, lengths of sides of the figure, and a figure code serving as an identifier for identifying the figure type such as rectangles and triangles.

When design pattern data serving as the figure data is input to the reference image generation circuit 112, the data is developed into data for each figure, and then, the figure code, the figure dimensions, and others indicating the figure shape in each figure data are interpreted. Then, the reference image generation circuit 112 develops each figure data to design pattern image data in binary or multiple values as a pattern to be arranged in squares in units of grids of predetermined quantization dimensions, and outputs the developed data. In other words, the reference image generation circuit 112 reads design data, calculates the occupancy rate of a figure in the design pattern, for each square region obtained by virtually dividing the inspection region into squares in units of predetermined dimensions, and outputs n-bit occupancy rate data. For example, it is preferable to set one square as one pixel. Assuming that one pixel has a resolution of ½⁸ (= 1/256), the occupancy rate in each pixel is calculated by allocating sub-regions, each having 1/256 resolution, which correspond to the region of a figure arranged in the pixel. Then, it is generated as 8-bit occupancy data. Such square regions (inspection pixels) can be corresponding to (commensurate with) pixels of measured data.

Next, the reference image generation circuit 112 performs filtering processing on design image data of a design pattern which is image data of a figure, using a predetermined filter function. Thereby, it becomes possible to match/fit the design image data being design side image data, whose image intensity (gray scale level) is represented by digital values, with image generation characteristics obtained by irradiation with the multiple primary electron beams 20. Image data for each pixel of a generated reference image is output to the comparison circuit 108. The reference image data transmitted into the comparison circuit 108 is stored in the storage device 52.

Next, the alignment unit 57 reads the frame image 31 serving as an inspection image, and a reference image corresponding to the frame image 31 concerned, and provides alignment between both the images, based on units of sub-pixels smaller than units of pixels. For example, the alignment can be performed by a least squares method.

Then, the comparison unit 58 compares a secondary electron image of the substrate 101 placed on the stage 105 with a predetermined image. Specifically, the comparison unit 58 compares, for each pixel, the frame image 31 and the reference image. The comparison unit 58 compares them, for each pixel, based on predetermined determination conditions so as to determine whether there is a defect such as a shape defect. For example, if a difference in gray scale level for each pixel is larger than a determination threshold Th, it is determined that there is a defect. Then, the comparison result is output. It may be output to the storage device 109 or the memory 118, or alternatively, output from the printer 119.

In the examples described above, the die-to-database inspection is performed. However, it is not limited thereto. A die-to-die inspection may be performed. In the case of the die-to-die inspection, alignment and comparison that have been described above are carried out between the frame image 31 (die 1) to be inspected and another frame image 31 (die 2) (another example of a reference image) in which there is formed the same pattern as that of the frame image 31 to be inspected.

According to the first embodiment, as described above, it is possible to identify a desired beam in multiple secondary electron beams.

### Second Embodiment

Although the mark member is described, in the first embodiment, on which four isolated patterns 12, for example, are formed to have the same positional relationship as that of four irradiation positions, at the height position of the surface of the substrate 101 (target object), of four corner beams, it is not limited thereto. A second embodiment describes the configuration where the number of isolated patterns is one. The configuration of the inspection apparatus 100 in the second embodiment is the same as that of FIG. 1. The contents of the second embodiment may be the same as those of the first embodiment except for what is particularly described below.

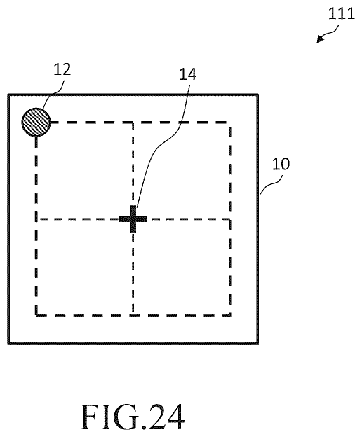

FIG. 24 is an illustration showing an example of a mark member according to the second embodiment. In FIG. 24, the mark member 111 includes the base body 10, one isolated pattern 12, and one alignment mark 14. Both the alignment mark 14 and the isolated pattern 12 are formed on the substrate 10. The relative positional relationship between the alignment mark 14 and the isolated pattern 12 is determined in advance.

Specifically, when the alignment mark 14 is at the irradiation position, flush in height with the surface of the substrate 101 (target object), of a representative primary electron beam (for example, center primary electron beam) of the multiple primary electron beams 20, the isolated pattern 12 is formed to have the same positional relationship as that of the irradiation position, flush in height with the substrate 101 (target object), of one primary electron beam having been determined in advance in the multiple primary electron beams 20. In the case of FIG. 24, when the alignment mark 14 is at the irradiation position, flush in height with the surface of the substrate 101 (target object), of the center beam of the multiple primary electron beams 20, the isolated pattern 12 is formed to have the same positional relationship as that of the irradiation position, flush in height with the surface of the substrate 101 (target object), of the primary electron beam of the upper left corner in the multiple primary electron beams 20.

Preferably, the isolated pattern 12 is circular or rectangular (including square). FIG. 24 shows the case of a circular isolated pattern. The isolated pattern 12 is formed to be larger than each of the multiple primary electron beams 20 on the surface of the substrate 101, and smaller than the pitch between adjacent primary electron beams.

With respect to the base body 10, a material 1 (first material) is used for at least its surface. As the material 1, it is preferable to use silicon (Si), for example. With respect to the isolated pattern 12, a material 2 (second material) being different from the material 1 is used. As the material 2, one of, for example, nickel (Ni), gold (Au), chromium (Cr), and platinum (Pt) is used. With respect to the alignment mark 14, a material 3 (third material) being different from the materials 1 and 2 is used. As the material 3, titanium (Ti) is used, for example.

Although it has been described that the yield of the material 2 of the isolated pattern 12 is higher than that of the material 1 of the base body 10, it is not limited thereto. It is also preferable that the yield of the material 2 of the isolated pattern 12 is lower than that of the material 1 of the base body 10. For example, as the material 2, beryllium (Be), etc. whose yield is thoroughly lower than that of Si can also preferably be used.

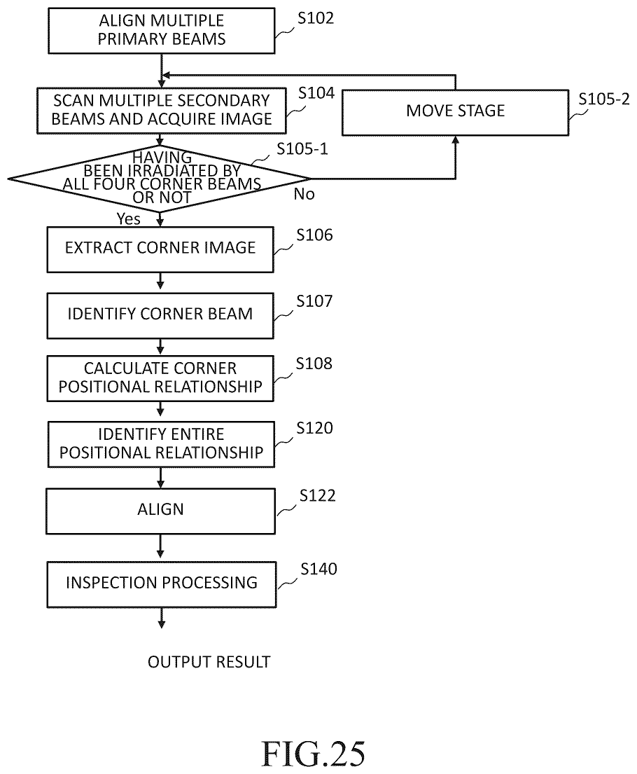

FIG. 25 is a flowchart showing an example of main steps of an inspection method according to the second embodiment. FIG. 25 is the same as FIG. 9 except that a determination step (S105-1) is added between the multiple-secondary-beam scanning and image acquisition step (S104) and the corner image extraction step (S106), and further, a stage moving step (S105-2) is added.

The contents of the multiple-primary-beam alignment step (S102) are the same as those of the first embodiment. Thereby, the multiple primary electron beams 20 can be aligned with the mark member 111. By this alignment, in the case of FIG. 24, the isolated pattern 12 has the same positional relationship as that of the irradiation position, flush in height with the surface of the substrate 101 (target object), of the primary electron beam of the upper left corner, for example, in the multiple primary electron beams 20.

After the alignment, the beam selection control circuit 136 controls the drive mechanism 211 to move the beam selection aperture substrate 210 so that the large aperture may be located on the trajectory of the multiple primary electron beams 20. Thereby, all of the multiple primary electron beams 20 can pass through the large aperture.

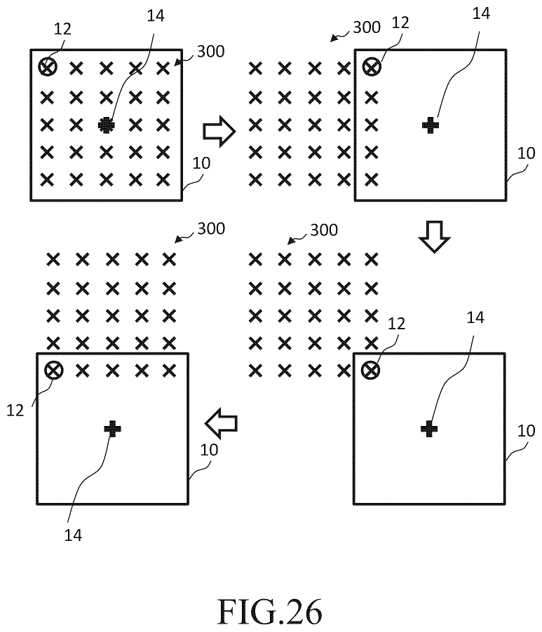

FIG. 26 is an illustration showing an example of a positional relationship between multiple primary electron beams and a mark member according to the second embodiment. Due to the multiple-primary-beam alignment step (S102), the present state is the one shown by the upper left illustration in FIG. 26. In such a state of position relationship, an image is acquired.

In the multiple-secondary-beam scanning and image acquisition step (S104), in the state where alignment of the multiple primary electron beams 20 has been performed using the alignment mark 14, the primary electron optical system 151 irradiates the mark member 111 with the multiple primary electron beams 20. In other words, the primary electron optical system 151 irradiates the mark member 111 with the multiple primary electron beams 20 in the state where the stage 105 has been moved so that the isolated pattern 12 may be located at the irradiation position, which is flush in height with the surface of the substrate 101, of a primary electron beam having been determined in advance in the multiple primary electron beams 20. Specifically, it operates as follows: The image acquisition mechanism 150 applies the multiple primary electron beams 20 onto the stage 105 in a stopped state. At this time, the deflectors 208 and 209 align the center of the multiple primary electron beams 20 with the position of the trajectory central axis of the multiple primary electron beams. If, without being deflected, the center of the multiple primary electron beams 20 is at the trajectory central axis of the multiple primary electron beams 20, it is acceptable not to provide deflection. Thereby, the scanning center position of the scanning range of each primary electron beam is continuously irradiated with each primary electron beam concerned.

The deflector 226 (deflector in the secondary electron optical system) scans the multiple secondary electron beams 300, emitted from the mark member 111 due to irradiation of the multiple primary electron beams 20, over a plurality of detection elements of the multi-detector 222. The contents are the same as those of the first embodiment.

The multi-detector 222 detects the multiple secondary electron beams 300 emitted from the mark member 111 due to irradiation of the mark member 111 with the multiple primary electron beams 20, and outputs detected image data. In other words, the multi-detector 222 detects the multiple secondary electron beams 300 by a plurality of detection elements (first detection element) arrayed in a grid. Thereby, each detection element acquires an aperture image of the detector aperture array substrate 225. Each detection element acquires images of a plurality of secondary electron beams passing over the detection element concerned due to a scan operation of the multiple secondary electron beams 300. Actually, beams having passed through the openings in the detector aperture array substrate 225 are detected. Therefore, a plurality of aperture images are detected by each detection element.

Detection data on a secondary electron detected by each detection element is output to the detection circuit 106 in the order of measurement. In the detection circuit 106, the detection data in analog form is converted into digital data by an A-D converter (not shown), and stored in the chip pattern memory 123. Then, the obtained secondary electron image data is output to the alignment circuit 134. In the alignment circuit 134, the secondary electron image data (detected image) is stored in the storage device 61.

In the obtained image at the upper left in FIG. 26, for example, the brightness of the aperture image of the upper left corner beam is higher than those of aperture images of the other secondary electron beams.

In the determination step (S105-1), the control computer 110 determines whether the isolated pattern 12 has been irradiated with all the four corner beams. When the isolated pattern 12 has not yet been irradiated by all the four corner beams, it proceeds to the stage moving step (S105-2). When the isolated pattern 12 has been irradiated by all the four corner beams, it proceeds to the corner image extraction step (S106).

In the stage moving step (S105-2), the stage control circuit 114 moves, based on the position of the alignment mark 14, the stage 105 so that the isolated pattern 12 may be located at the position whose positional relationship is the same as the irradiation position, flush in height with the surface of the substrate 101 (target object), of one corner beam which has not yet been applied to the isolated pattern 12 in the four corner beams. Specifically, the stage 105 is moved to be in the state of the upper right of FIG. 26, for example. Thereby, the isolated pattern 12 has the same positional relationship as that of the irradiation position, which is flush in height with the surface of the substrate 101 (target object), of, for example, the primary electron beam of the upper right corner in the multiple primary electron beams 20. The design relative distance can be used as the relative distance, on the surface of the target object, between the position of the center primary electron beam, being the position of the alignment mark 14, and the position of the primary electron beam of the upper right corner.

Then, it returns to the multiple-secondary-beam scanning and image acquisition step (S104), and until the isolated pattern 12 has been irradiated by all the four corner beams, the multiple-secondary-beam scanning and image acquisition step (S104), the determination step (S105-1), and the stage moving step (S105-2) are repeated.

Now, the case of FIG. 26 will be described specifically. There is an assumption that the direction (angle) of the arrangement of the multiple primary electron beams 20 is coincident with that of the movement direction of the stage 105 mounted on the substrate 101 (target object). Furthermore, the multiple primary electron beams 20 are aligned, on the surface of the substrate 101 (target object), in a square grid. The existence range (length and width) of the multiple primary electron beams 20 is already known.

First, the stage 105 is moved so that the center beam can be aligned with the alignment mark 14, (the upper left in FIG. 26). Thereby, the upper left corner beam is aligned with the position of the isolated pattern 12. Since the upper left corner beam is detected, by the secondary electron detector, as having a higher luminance than the other beams, it is possible to identify that it is the upper left corner beam.

Next, the stage 105 is moved in the +x direction (the right horizontal direction in FIG. 26) by the length of one side of the multiple beams, (the upper right in FIG. 26). Thereby, the upper right corner beam is aligned with the position of the isolated pattern 12. Since the upper right corner beam is detected, by the secondary electron detector, as having a higher luminance than the other beams, it is possible to identify that it is the upper right corner beam.

Next, the stage 105 is moved in the −y direction (the lower vertical direction in FIG. 26) by the length of one side of the multiple beams, (the lower right in FIG. 26). Thereby, the lower right corner beam is aligned with the position of the isolated pattern 12. Since the lower right corner beam is detected, by the secondary electron detector, as having a higher luminance than the other beams, it is possible to identify that it is the lower right corner beam.

Next, the stage 105 is moved in the −x direction (the left horizontal direction in FIG. 26) by the length of one side of the multiple beams, (the lower left in FIG. 26). Thereby, the lower left corner beam is aligned with the position of the isolated pattern 12. Since the lower left corner beam is detected, by the secondary electron detector, as having a higher luminance than the other beams, it is possible to identify that it is the lower left corner beam.

As described above, the four corner beams can be identified. Thus, even if there are not four isolated patterns, the purpose of the present Embodiment can be achieved.

As shown in the example of FIG. 26, depending on the positional relationship between the multiple primary electron beams 20 and the mark member 111, there may be a case where a part of the multiple primary electron beams 20 irradiates a position outside the mark member 111. However, even in such a case, all the multiple primary electron beams 20 can irradiate, at least once, the mark member 111. FIG. 26 shows the case where the isolated pattern 12 has the same positional relationship as that of the irradiation position, flush in height with the surface of the substrate 101 (target object), of, for example, the primary electron beam of the upper left corner in the multiple primary electron beams 20. Therefore, each detection element can detect a plurality of aperture images.

As described above, with respect to each corner beam, an image can be obtained in which the brightness of the aperture image of the corner beam concerned is higher than those of aperture images of the other secondary electron beams. Thus, respective corner beams can be identified based on the four images.

The contents of each step after the corner image extraction step (S106) are the same as those of the first embodiment.

Thus, as described above, according to the second embodiment, the same effect as that of the first embodiment can be obtained even when the mark member 111 is used on which one isolated pattern 12 and one alignment mark 14 are formed.

### Third Embodiment

According to a third embodiment, the mark member 111 is used where one isolated pattern 12 is formed on the substrate 10 and no alignment mark is formed. The configuration of the inspection apparatus 100 in the third embodiment is the same as that of FIG. 1. The contents of the third embodiment may the same as those of the first or second embodiment except for what is particularly described below.

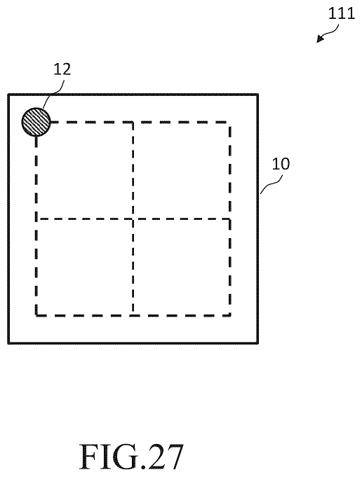

FIG. 27 is an illustration showing an example of a mark member according to the third embodiment. In FIG. 27, the mark member 111 includes the base body 10 and one isolated pattern 12. The isolated pattern 12 is formed on the substrate 10. When the isolated pattern 12 has the same positional relationship as that of the irradiation position, flush in height with the surface of the substrate 101 (target object), of one primary electron beam having been determined in advance in the multiple primary electron beams 20, the isolated pattern 12 is formed at the position where the substrate 10 can be irradiated with the whole of the multiple primary electron beams 20. In the example of FIG. 27, when the isolated pattern 12 has the same positional relationship as that of the irradiation position, flush in height with the surface of the substrate 101 (target object), of a primary electron beam of the upper left corner in the multiple primary electron beams 20, the mark member 111 is formed such that the irradiation position of all the multiple primary electron beams 20 is located within the substrate 10. The example of FIG. 27 is the same as FIG. 24 except that the alignment mark 14 has been omitted.

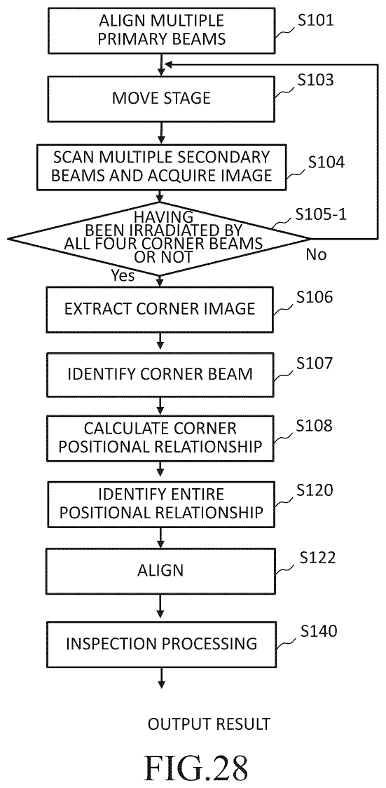

FIG. 28 is a flowchart showing an example of main steps of an inspection method according to the third embodiment. FIG. 28 is the same as FIG. 9 except that a multiple-primary-beam alignment step (S101) and a stage moving step (S103) are performed instead of the multiple-primary-beam alignment step (S102), and that the determination step (S105-1) is added between the multiple-secondary-beam scanning and image acquisition step (S104) and the corner image extraction step (S106).

In the multiple-primary-beam alignment step (S101), alignment of the multiple primary electron beams 20 is performed using the isolated pattern 12. Specifically, it operates as follows: First, the stage 105 is moved so that the isolated pattern 12 may be located on the trajectory central axis of the multiple primary electron beams 20. The beam selection control circuit 136 controls the drive mechanism 211 to move the beam selection aperture substrate 210 so that the small aperture may be located on the trajectory of the center primary electron beam. Thereby, the beam selection aperture substrate 210 selectively passes the center primary electron beam of the multiple primary electron beams 20. The other remaining primary electron beams are blocked by the beam selection aperture substrate 210.

Next, the deflector 208 and/or the deflector 209 scan the center primary electron beam over the isolated pattern 12 by beam deflection. Then, the multi-detector 222 detects secondary electron beams emitted from the isolated pattern 12 and its circumference. Although it is desirable here to detect a secondary electron beam by using the center detection element, in the multi-detector 222, which detects the center secondary electron beam corresponding to the center primary electron beam, another detection element may also be used for detection. The stage 105 is moved so that the image of the isolated pattern 12 may be located at the center of an obtained secondary electron image. Alternatively, the deflector 208 and the deflector 209 deflect the center primary electron beam so that the image of the isolated pattern 12 may be located at the center of an obtained secondary electron image. Thereby, the isolated pattern 12 can be aligned with the center primary electron beam.

In the stage moving step (S103), the stage control circuit 114 moves the stage 105 so that the isolated pattern 12 may be located at the position whose positional relationship is the same as the irradiation position, flush in height with the surface of the substrate 101 (target object), of, for example, the primary electron beam of the upper left corner in the multiple primary electron beams 20. Thereby, the multiple primary electron beams 20 can be aligned with the mark member 111.

As described above, alignment can be performed between the multiple primary electron beams 20 and the mark member 111. By this alignment, in the case of FIG. 27, the isolated pattern 12 has the same positional relationship as that of the irradiation position, flush in height with the surface of the substrate 101 (target object), of, for example, the primary electron beam of the upper left corner in the multiple primary electron beams 20. The design relative distance can be used as the relative distance, on the surface of the target object, between the position of the primary electron beam of the upper left corner and the position of the center primary electron beam.

After the alignment, the beam selection control circuit 136 controls the drive mechanism 211 to move the beam selection aperture substrate 210 so that the large aperture may be located on the trajectory of the multiple primary electron beams 20. Thereby, all of the multiple primary electron beams 20 can pass through the large aperture.

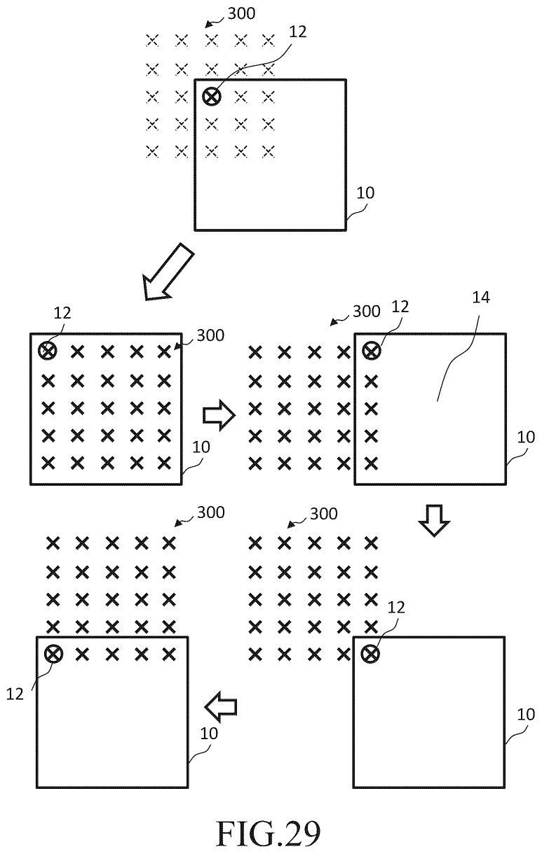

FIG. 29 is an illustration showing an example of positional relationship between multiple primary electron beams and a mark member according to the third embodiment. By the multiple-primary-beam alignment step (S101), the state of the figure at the upper row in FIG. 29 has proceeded to that at the middle left. An image is acquired in this state of positional relationship.

The contents of the multiple-secondary-beam scanning and image acquisition step (S104) are the same as those of the second embodiment.

In the obtained image at the middle left in FIG. 29, for example, the brightness of the aperture image of the upper left corner beam is higher than those of aperture images of the other secondary electron beams.

In the determination step (S105-1), the control computer 110 determines whether the isolated pattern 12 has been irradiated with all the four corner beams. When the isolated pattern 12 has not yet been irradiated by all the four corner beams, it proceeds to the stage moving step (S103). When the isolated pattern 12 has been irradiated by all the four corner beams, it proceeds to the corner image extraction step (S106).

In the stage moving step (S103), the stage control circuit 114 moves the stage 105 so that the isolated pattern 12 may be located at the position whose positional relationship is the same as the irradiation position, flush in height with the surface of the substrate 101 (target object), of one corner beam which has not yet been applied to the isolated pattern 12 in the four corner beams. Specifically, the stage 105 is moved to be in the state of the middle right of FIG. 29, for example. Thereby, the isolated pattern 12 has the same positional relationship as that of the irradiation position, flush in height with the surface of the substrate 101 (target object), of, for example, the primary electron beam of the upper right corner in the multiple primary electron beams 20. The design relative distance can be used as the relative distance, on the surface of the target object, between the position of the primary electron beam of the upper left corner and the position of the primary electron beam of the upper right corner.

Then, the stage moving step (S103), the multiple-secondary-beam scanning and image acquisition step (S104), and the determination step (S105-1) are repeated until the isolated pattern 12 has been irradiated by all the four corner beams.

Now, the case of FIG. 29 will be described specifically.

First, the stage 105 is moved so that the center beam can be aligned with the isolated pattern 12, (the upper row in FIG. 29).

Next, the stage 105 is moved in the +x direction (the right horizontal direction in FIG. 29) by half the length of one side of the multiple primary electron beams, and in the −y direction (the lower vertical direction in FIG. 29) by half the length of one side of the multiple primary electron beams, (the middle left in FIG. 29). Thereby, the upper left corner beam is aligned with the position of the isolated pattern 12. Since the upper left corner beam is detected, by the secondary electron detector, as having a higher luminance than the other beams, it is possible to identify that it is the upper left corner beam.

Next, the stage 105 is moved in the +x direction (the right horizontal direction in FIG. 29) by the length of one side of the multiple primary electron beams, (the middle right in FIG. 29). Thereby, the upper right corner beam is aligned with the position of the isolated pattern 12. Since the upper right corner beam is detected, by the secondary electron detector, as having a higher luminance than the other beams, it is possible to identify that it is the upper right corner beam.

Next, the stage 105 is moved in the −y direction (the lower vertical direction in FIG. 29) by the length of one side of the multiple primary electron beams, (the lower right in FIG. 29). Thereby, the lower right corner beam is aligned with the position of the isolated pattern 12. Since the lower right corner beam is detected, by the secondary electron detector, as having a higher luminance than the other beams, it is possible to identify that it is the lower right corner beam.

Next, the stage 105 is moved in the −x direction (the left horizontal direction in FIG. 29) by the length of one side of the multiple primary electron beams, (the lower left in FIG. 29). Thereby, the lower left corner beam is aligned with the position of the isolated pattern 12. Since the lower left corner beam is detected, by the secondary electron detector, as having a higher luminance than the other beams, it is possible to identify that it is the lower left corner beam.

As described above, the four corner beams can be identified. Accordingly, even if there is no alignment mark, the purpose of the present Embodiment can be achieved.

As shown in the example of FIG. 29, depending on the positional relationship between the multiple primary electron beams 20 and the mark member 111, there may be a case where a part of the multiple primary electron beams 20 irradiates a position outside the mark member 111. However, even in such a case, all the multiple primary electron beams 20 can irradiate, at least once, the mark member 111. FIG. 29 shows the case where the isolated pattern 12 has the same positional relationship as that of the irradiation position, flush in height with the surface of the substrate 101 (target object), of, for example, the primary electron beam of the upper left corner in the multiple primary electron beams 20. Therefore, each detection element can detect a plurality of aperture images.

As described above, with respect to each corner beam, an image can be obtained in which the brightness of the aperture image of the corner beam concerned is higher than those of aperture images of the other secondary electron beams. Thus, respective corner beams can be identified based on the four images.

The contents of each step after the corner image extraction step (S106) are the same as those of the first embodiment.

Thus, as described above, according to the third embodiment, the same effect as the first embodiment can be obtained even when the mark member 111 is used on which one isolated pattern 12 is formed.

### Fourth Embodiment

According to a fourth embodiment, the mark member 111 is used where a plurality of alignment marks and one isolated pattern 12 are formed on the substrate 10. The configuration of the inspection apparatus 100 in the fourth embodiment is the same as that of FIG. 1. The contents of the fourth embodiment may the same as those of any of the first to third embodiments except for what is particularly described below.

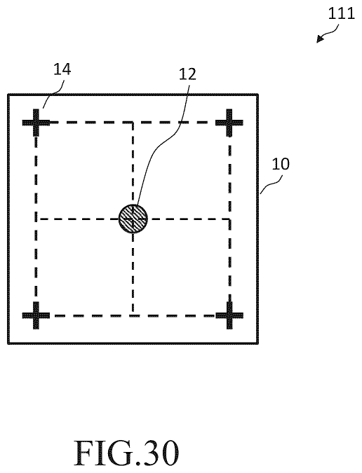

FIG. 30 is an illustration showing an example of a mark member according to the fourth embodiment. In FIG. 30, the mark member 111 includes the base body 10, one isolated pattern 12, and four alignment marks 14. Both the isolated pattern 12 and the four alignment marks 14 are formed on the substrate 10. In FIG. 30, when the isolated pattern 12 is at the irradiation position, flush in height with the surface of the substrate 101, of the center primary electron beam in the multiple primary electron beams 20, the four alignment marks 14 are formed to have the same positional relationship as the irradiation positions, flush in height with the surface of the substrate 101, of four corner beams in the multiple primary electron beams 20, each of the four alignment marks 14 being corresponding to a different one of the four corner beams in the multiple primary electron beams 20. In other words, with respect to each alignment mark 14, when the alignment mark 14 concerned is at the irradiation position, flush in height with the surface of the substrate 101, of the center primary electron beam of the multiple primary electron beams 20, the isolated pattern 12 has the same positional relationship as that of the irradiation position, flush in height with the surface of the substrate 101, of one corner beam in the four corner beams in the multiple primary electron beams 20, the one corner beam for the alignment mark 14 concerned being different from the other corner beams for the other alignment marks 14 in the four alignment marks 14.

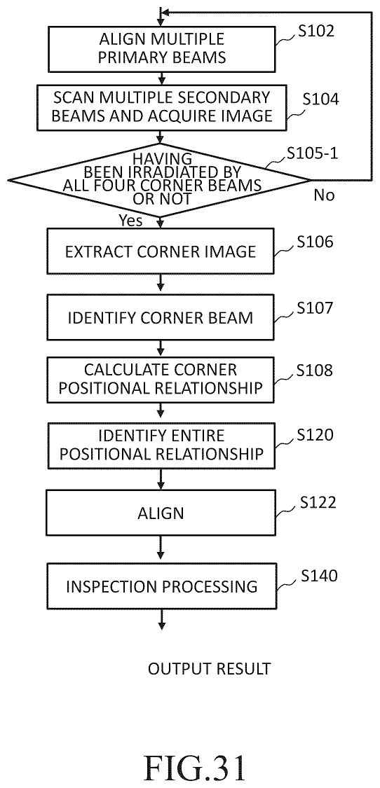

FIG. 31 is a flowchart showing an example of main steps of an inspection method according to the fourth embodiment. FIG. 31 is the same as FIG. 9 except that the determination step (S105-1) is added between the multiple-secondary-beam scanning and image acquisition step (S104) and the corner image extraction step (S106).

The contents of the multiple-primary-beam alignment step (S102) are the same as those of the first embodiment. However, here, one of the four alignment marks 14 is used. For example, the upper left alignment mark 14 is used. Thereby, the first time alignment between the multiple primary electron beams 20 and the mark member 111 can be performed.

In the case of FIG. 30, for example, by the alignment using the upper left alignment mark 14, the isolated pattern 12 has the same positional relationship as that of the irradiation position, flush in height with the surface of the substrate 101 (target object), of the primary electron beam of the lower right corner, for example, in the multiple primary electron beams 20.

After the alignment, the beam selection control circuit 136 controls the drive mechanism 211 to move the beam selection aperture substrate 210 so that the large aperture may be located on the trajectory of the multiple primary electron beams 20. Thereby, all of the multiple primary electron beams 20 can pass through the large aperture.

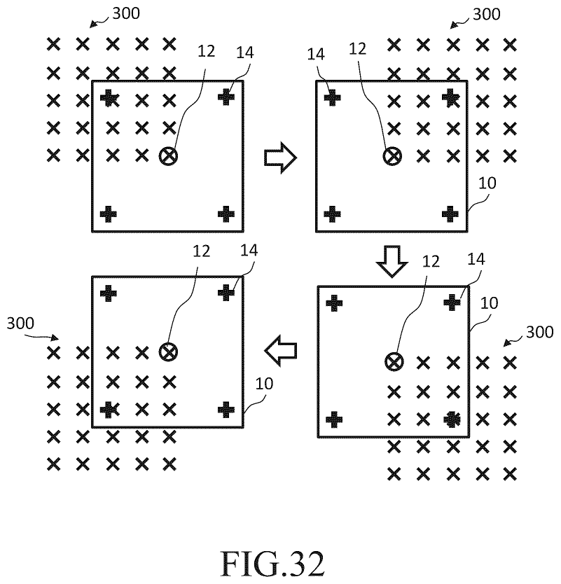

FIG. 32 is an illustration showing an example of positional relationship between multiple primary electron beams and a mark member according to the fourth embodiment. Due to the first time multiple-primary-beam alignment step (S102), the present state is the one shown by the upper left illustration in FIG. 32. In such a state of position relationship, an image is acquired.

The contents of the multiple-secondary-beam scanning and image acquisition step (S104) are the same as those of the second embodiment.

In the obtained image at the upper left in FIG. 32, for example, the brightness of the aperture image of the lower right corner beam is higher than those of aperture images of the other secondary electron beams.

In the determination step (S105-1), the control computer 110 determines whether the isolated pattern 12 has been irradiated with all the four corner beams. When the isolated pattern 12 has not yet been irradiated by all the four corner beams, it proceeds to the multiple-primary-beam alignment step (S102). When the isolated pattern 12 has been irradiated by all the four corner beams, it proceeds to the corner image extraction step (S106).

In the multiple-primary-beam alignment step (S102), alignment of the multiple primary electron beams is performed using the alignment mark 14 which has not yet been used in the four alignment marks 14. Specifically, for example, in the second time multiple-primary-beam alignment step (S102), as shown in the figure at the upper right of FIG. 32, alignment of the multiple primary beams is performed using the upper right alignment mark 14.

Then, until the isolated pattern 12 has been irradiated by all the four corner beams, the multiple-primary-beam alignment step (S102), the multiple-secondary-beam scanning and image acquisition step (S104), and the determination step (S105-1) are repeated. According to the fourth embodiment, the multiple-primary-beam alignment step (S102) performed totally four times and the multiple-secondary-beam scanning and image acquisition step (S104) performed totally four times are carried out.

Now, the case of FIG. 32 will be described specifically.

First, the stage 105 is moved so that the center beam can be aligned with the upper left alignment mark 14, (the upper left in FIG. 32). Thereby, the lower right corner beam is aligned with the position of the isolated pattern 12. Since the lower right corner beam is detected, by the secondary electron detector, as having a higher luminance than the other beams, it is possible to identify that it is the lower right corner beam.

Next, the stage 105 is moved so that the center beam can be aligned with the upper right alignment mark 14, (the upper right in FIG. 32). Thereby, the lower left corner beam is aligned with the position of the isolated pattern 12. Since the lower left corner beam is detected, by the secondary electron detector, as having a higher luminance than the other beams, it is possible to identify that it is the lower left corner beam.

Next, the stage 105 is moved so that the center beam can be aligned with the lower right alignment mark 14, (the lower right in FIG. 32). Thereby, the upper left corner beam is aligned with the position of the isolated pattern 12. Since upper left corner beam is detected, by the secondary electron detector, as having a higher luminance than the other beams, it is possible to identify that it is the upper left corner beam.

Next, the stage 105 is moved so that the center beam can be aligned with the lower left alignment mark 14, (the lower left in FIG. 32). Thereby, the upper right corner beam is aligned with the position of the isolated pattern 12. Since the upper right corner beam is detected, by the secondary electron detector, as having a higher luminance than the other beams, it is possible to identify that it is the upper right corner beam.

As described above, the four corner beams can be identified. Accordingly, even if the accuracy of the stage is not sufficient, or the accuracy of the mark position on the stage is poor, it can be coped with.

As shown in the example of FIG. 32, in the four positional relationships between the multiple primary electron beams 20 and the mark member 111, only ¼ beams of the multiple primary electron beams 20 can be located within the substrate 10 of the mark member 111. However, by performing beam irradiation while changing the alignment mark 14, the mark member 111 can be at least once irradiated with each beam of the multiple primary electron beams 20. In the case of FIG. 32, the mark member 111 can be irradiated, in order, with ¼ beams at the lower right of the multiple primary electron beams 20, ¼ beams at the lower left, ¼ beams at the upper left, and ¼ beams at the upper right. Therefore, each detection element can detect a plurality of aperture images.

As described above, with respect to each corner beam, an image can be obtained in which the brightness of the aperture image of the corner beam concerned is higher than those of aperture images of the other secondary electron beams. Thus, respective corner beams can be identified based on the four images.

The contents of each step after the corner image extraction step (S106) are the same as those of the first embodiment.

As described above, according to the fourth embodiment, by aligning the center primary electron beam with each alignment mark 14 in order, the four corner beams can be automatically aligned with the isolated pattern 12 in order. Furthermore, according to the fourth embodiment, even when the movement direction of the stage 105 and the arrangement direction of the beam array are not coincident with each other due to insufficient accuracy, it can be coped with. The same effect as that of the first embodiment can be acquired.

Although, in any of the embodiments described above, the size of the base body 10 is a little larger than that of the multiple primary electron beams, it is not limited thereto. Rather, it is desirable that the size of the base body 10 is sufficiently larger than that of the multiple primary electron beams. This is because to avoid an influence on distribution of the multiple primary electron beams due to change of an electric field at the edge of the base body 10. For example, in FIGS. 26, 29, and 32, if the size of the base body 10 is made sufficiently larger than three times the size of the multiple primary electron beams, the multiple primary electron beams are not applied to the outside the base body 10 even when the stage is shifted, and, further, the influence on the electric field at the edge of the base body 10 can be avoided.

In the above description, each “ . . . circuit” includes processing circuitry. The processing circuitry includes an electric circuit, a computer, a processor, a circuit board, a quantum circuit, a semiconductor device, or the like. Each “ . . . circuit” may use common processing circuitry (the same processing circuitry), or different processing circuitry (separate processing circuitry). Programs for causing a processor, etc. to execute processing may be stored in a recording medium, such as a magnetic disk drive, a magnetic tape drive, FD, ROM (Read Only Memory) or the like. For example, the position circuit 107, the comparison circuit 108, the reference image generation circuit 112, the stage control circuit 114, the lens control circuit 124, the blanking control circuit 126, the deflection control circuit 128, the detector stage control circuit 130, the E×B control circuit 133, the alignment circuit 134, and the beam selection control circuit 136 may be formed by at least one processing circuit described above. For example, processing in these circuits may be carried out by the control computer 110.

Embodiments have been explained referring to specific examples described above. However, the present invention is not limited to these specific examples. Although FIG. 1 shows the case where the multiple primary electron beams 20 are formed by the shaping aperture array substrate 203 irradiated with one beam from the electron gun 201 serving as an irradiation source, it is not limited thereto. The multiple primary electron beams 20 may be formed by irradiation with a primary electron beam from each of a plurality of irradiation sources.

While the apparatus configuration, control method, and others not directly necessary for explaining the present invention are not described, some or all of them can be appropriately selected and used on a case-by-case basis when needed.

Furthermore, any multiple-beam image acquisition apparatus and multiple-beam image acquisition method that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multiple-beam image acquisition apparatus comprising:
a stage configured to mount thereon a target object;
a mark member arranged on the stage and configured to include a base body having at least a surface made from a first material, a plurality of isolated patterns, formed on the base body, having a same positional relationship as that of a plurality of irradiation positions, flush in height with a surface of the target object, of a plurality of beams having been determined in advance in multiple primary electron beams, and being made from a material different from the first material, and an alignment mark;
an electron optical system configured to irradiate the mark member with the multiple primary electron beams in a state where alignment of the multiple primary electron beams has been performed using the alignment mark; and
a multi-detector configured to detect multiple secondary electron beams emitted from the mark member due to that the mark member is irradiated with the multiple primary electron beams.

2. The apparatus according to claim 1, wherein, as the plurality of beams, four corner beams of the multiple primary electron beams are used.

3. The apparatus according to claim 1, wherein
the plurality of isolated patterns are made from a second material, and
an emission ratio of a secondary electron beam to a primary electron beam of the first material is different from that of the second material.

4. The apparatus according to claim 1 further comprising:
an identification circuit configured to identify, using a detected image of the multiple secondary electron beams, the plurality of beams, based on a difference between intensities in the detected image.

5. The apparatus according to claim 1, wherein each isolated pattern of the plurality of isolated patterns is larger than a size of each primary electron beam of the multiple primary electron beams, and smaller than a pitch between adjacent primary electron beams.

6. The apparatus according to claim 1, wherein
the plurality of isolated patterns are formed at a same array pitch as that of four corner beams of the multiple primary electron beams on the surface of the target object, and
the alignment mark is formed at a center of four isolated patterns.

7. A multiple-beam image acquisition method comprising:
performing an alignment of multiple primary electron beams, using an alignment mark;
applying the multiple primary electron beams, in a state where the multiple primary electron beams have been aligned using the alignment mark, to a mark member, arranged on a stage to mount a target object thereon, which includes a base body having at least a surface made from a first material, a plurality of isolated patterns formed having a same positional relationship as that of a plurality of irradiation positions, flush in height with a surface of the target object, of a plurality of beams determined in advance in multiple primary electron beams, on the base body, and being made from a material different from the first material, and the alignment mark; and
detecting multiple secondary electron beams emitted from the mark member due to that the mark member is irradiated with the multiple primary electron beams, and outputting detected image data.

8. A multiple-beam image acquisition apparatus comprising:
a stage configured to mount thereon a target object and to be movable;
a mark member arranged on the stage and configured to include a base body having at least a surface made from a first material, and one isolated pattern, formed on the base body, being made from a material different from the first material;
an electron optical system configured to irradiate the mark member with multiple primary electron beams in a state where the stage has been moved so that the one isolated pattern is located at an irradiation position, flush in height with a surface of the target object, of a beam determined in advance in the multiple primary electron beams; and
a multi-detector configured to detect multiple secondary electron beams emitted from the mark member due to that the mark member is irradiated with the multiple primary electron beams, wherein
the mark member further includes an alignment mark, and
in a case where the alignment mark is at an irradiation position, flush in height with the surface of the target object, of a representative beam in the multiple primary electron beams, the one isolated pattern is formed to have a same positional relationship as that of an irradiation position, flush in height with the surface of the target object, of one beam determined in advance in the multiple primary electron beams.

9. A multiple-beam image acquisition apparatus comprising:
a stage configured to mount thereon a target object and to be movable;
a mark member arranged on the stage and configured to include a base body having at least a surface made from a first material and, one isolated pattern, formed on the base body, being made from a material different from the first material;
an electron optical system configured to irradiate the mark member with multiple primary electron beams in a state where the stage has been moved so that the one isolated pattern is located at an irradiation position, flush in height with a surface of the target object, of a beam determined in advance in the multiple primary electron beams; and
a multi-detector configured to detect multiple secondary electron beams emitted from the mark member due to that the mark member is irradiated with the multiple primary electron beams, wherein
the mark member further includes four alignment marks, and
with respect to each of the four alignment marks, in a case where an alignment mark concerned is at an irradiation position, flush in height with the surface of the target object, of a center beam of the multiple primary electron beams, the one isolated pattern is formed to have a same positional relationship as that of an irradiation position, flush in height with the surface of the target object, of one corner beam in four corner beams of the multiple primary electron beams, the one corner beam for the alignment mark concerned being different from other corner beams for other alignment marks of the four alignment marks.

10. A multiple-beam image acquisition method comprising:
moving a stage, which is to mount thereon a target object, so that one isolated pattern, included in a mark member which is arranged on the stage and includes a base body having at least a surface made from a first material and the one isolated pattern formed on the base body and made from a material different from the first material, is located at an irradiation position, flush in height with a surface of the target object, of a beam determined in advance in multiple primary electron beams;
irradiating the mark member with the multiple primary electron beams, in a state where the one isolated pattern is at the irradiation position, flush in height with the surface of the target object, of the beam determined in advance; and
detecting multiple secondary electron beams emitted from the mark member due to that the mark member is irradiated with the multiple primary electron beams, and outputting detected image data, wherein
the mark member further includes an alignment mark, and
in a case where the alignment mark is at an irradiation position, flush in height with the surface of the target object, of a representative beam in the multiple primary electron beams, the isolated pattern is formed to have a same positional relationship as that of an irradiation position, flush in height with the surface of the target object, of one beam determined in advance in the multiple primary electron beams.

11. A multiple-beam image acquisition apparatus comprising:
a stage configured to mount thereon a target object;
a mark member arranged on the stage and configured to include a base body having at least a surface made from a first material, a plurality of isolated patterns, formed on the base body, having a same positional relationship as that of a plurality of irradiation positions, flush in height with a surface of the target object, of a plurality of beams determined in advance in multiple primary electron beams, and being made from a material different from the first material, and an alignment mark;
an electron optical system configured to irradiate one of the target object and the mark member with the multiple primary electron beams; and
a multi-detector configured to detect multiple secondary electron beams emitted due to that the one of the target object and the mark member is irradiated with the multiple primary electron beams.

12. A multiple-beam image acquisition method comprising:
moving a stage, which is to mount thereon a target object, so that one isolated pattern, included in a mark member which is arranged on the stage and includes a base body having at least a surface made from a first material and the one isolated pattern formed on the base body and made from a material different from the first material, is located at an irradiation position, flush in height with a surface of the target object, of a beam determined in advance in multiple primary electron beams;
irradiating the mark member with the multiple primary electron beams, in a state where the one isolated pattern is at the irradiation position, flush in height with the surface of the target object, of the beam determined in advance; and
detecting multiple secondary electron beams emitted from the mark member due to that the mark member is irradiated with the multiple primary electron beams, and outputting detected image data, wherein
the mark member further includes four alignment marks, and
with respect to each of the four alignment marks, in a case where an alignment mark concerned is at an irradiation position, flush in height with the surface of the target object, of a center beam of the multiple primary electron beams, the one isolated pattern is formed to have a same positional relationship as that of an irradiation position, flush in height with the surface of the target object, of one corner beam in four corner beams of the multiple primary electron beams, the one corner beam for the alignment mark concerned being different from other corner beams for other alignment marks of the four alignment marks.
